(19) United States
(12) Patent Application Publication
(10) Pub. No.: US 2009/0180269 A1
(43) Pub. Date: Jul. 16, 2009

(54) Diode connector, design system for that, and method of design for that

(75) Inventors: Yasutaka Nagaoka, Shizuoka (JP); Nobuhiko Suzuki, Shizuoka (JP); Hisafumi Maruo, Shizuoka (JP); Masashi Nagao, Shizuoka (JP); Takahiro Miyakawa, Shizuoka (JP)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: YAZAKI CORPORATION

(21) Appl. No.: 12/318,772

(22) Filed: Jan. 8, 2009

(30) Foreign Application Priority Data
Jan. 10, 2008 (JP) 2008-003141

(51) Int. Cl. G06F 17/50; H05K 7/18

(52) U.S. Cl. 361/813; 716/4

(57) ABSTRACT

For providing a design apparatus for designing a small diode connector durable for overcurrent flow easily in low cost, and a design method for designing the diode connector, and a diode connector durable for overcurrent flow to be small in low cost, the design apparatus 1 having a plurality of lead frames, a diode chip and a bridge and solder brazing these components includes a determining unit determining one of the name of the brazing alloy to be used as a solder and a total volume of the lead frames and the bridge when the other of the name of the brazing alloy and the total volume of the lead frames and the bridge is inputted, based on the inputted other and a correlation data of the total volume and a heat temperature of the diode chip.

The priority application Number Japan Patent Application 2008-003141 upon which this patent application is based is hereby incorporated by reference.

### BACKGROUND OF THE INVENTION

1. Field of the Invention

The present invention relates to a diode connector used for connecting a wiring harness wired in a vehicle such as a car, and a design system for that, and a method of design for that.

2. Description of the Related Art

In the car as the vehicle, many various electronic devices are mounted, and a wiring harness is wired for transmitting electric power and signals to the electronic devices. A diode connector having a diode for limiting electric current flow in one way may be used as a connector for connecting the wiring harnesses to each other or connecting the wiring harness and the electronic device.

The diode connector includes a plurality of lead frames, a diode chip arranged on the lead frames, a bridge connecting between the diode chip and the lead frames, and a solder welding the lead frame, the diode chip and the bridge to each other. For example, Patent Document 1, Japan Patent Published Application No. 2002-343504, should be referred.

The lead frames and the bridge perform to connect the wiring harnesses electrically and also to dissipate heat generated at the diode chip by electric current flow. A volume of the lead frame and a volume of the bridge are required to reduce a temperature of the solder welding the diode to the lead frame and the bridge by radiating the heat of the diode chip to protect from melting the solder when a permissible overcurrent defined based on pre-arcing time-current characteristic of a fuse in a same circuit.

High-melting-point lead solder having high melting point over 300° C. (hereafter, call high temperature solder) is usually used in the diode connector. Thereby, a total volume of the lead frame and the bridge can be designed to be small enough to dissipate heat of the diode chip against outer dimensions of the diode connector allowed for mounting in the car. In other words, design margin about the total volume of the lead frame and the bridge is large enough to easily design for radiating heat of the diode chip.

### SUMMARY OF THE INVENTION

### Objects To Be Solved

In the usual design method to enlarge an area (volume) of the lead frame within an allowable range as shown in Patent Document 1, the total volume of the lead frame and the diode chip required for dissipating the heat of the diode chip cannot be determined securely. Therefore, the lead frame and the bridge may be designed too large over requirements so that a material cost would be increased.

In resent years, influence of lead solder on an environment becomes a big issue. According to the diode connector, changing the high temperature lead solder to lead-free solder is proceeded. The lead-free solder has a lower melting point than that of the high temperature solder, and the lead-free solder having a 200° C. melting point is mainly used. Thereby, it is required for improving heat dissipation to increase the total volume of the lead frame and the bridge larger than that thereof using usual high temperature solder, so that the design margin about the total volume thereof is reduced and design becomes difficult.

When the diode connector is designed, the each required volume of the lead frame and the bridge cannot be determined. Thereby, repeating processes of producing a proto-type of the diode connector, measuring data of heat dissipation of the proto-type and optimizing the volumes by feed-backing the data to the process of designing the diode connector is required, so that design cost thereof would be increased.

Especially in the diode connector used in the car, compatibility with present diode connector is placed in importance, so that it is not easy to change the outer dimensions. Additionally, for avoiding cost-up according to new designs, commonly using the same component applied already, for example the present lead frame, is required. For the limitation about determining the total volume of the lead frame and the bridge, it becomes more difficult to design the diode connector.

To overcome the above problem, an object of the present invention is to provide a design apparatus for designing a small diode connector durable for overcurrent flow easily in low cost, and a design method for designing the diode connector, and a diode connector durable for overcurrent flow to be small in low cost.

### How To Attain the Object of the Present Invention

In order to attain the object of the present invention, a design apparatus for designing a diode connector is characterized in that the diode connector includes a plurality of lead frames having a joint and a terminal formed integrally with the joint; at least one diode chip arranged on the joint of at least one of the plurality of lead frames; a bridge connecting between the diode chip and the joint of at least other one of the plurality of lead frames; and a solder welding the joint of the lead frame, the diode chip and the bridge to each other, and the design apparatus includes a memory device storing melting point data of a plurality of brazing alloys, and correlation data between a total volume of the lead frames and the bridge, and heating temperature of the diode chip; an input device for inputting one of a name of the brazing alloy to be used selected from the plurality of brazing alloys and the total volume; and a determination device for determining the other one of the name of the brazing alloy and the total volume based on the one of the name of the brazing alloy and the total volume, which is inputted into the input device, and the melting point data and correlation data, which are stored in the memory device.

According to the present invention mentioned above, the memory device has the melting point data of the plurality of brazing alloys, and the correlation data between the total volume of the lead frames and the bridge, and heating temperature of the diode chip. Therefore, by corresponding the melting point data and the heat temperature, a relation between the name of the brazing alloy and the required total volume when using the brazing alloy can be given.

Then, when the one of the name of the brazing alloy and the total volume is inputted from the input device, the determination device determines the other one of the name of the brazing alloy and the total volume based on the inputted one, the melting point data and the correlation data. Thus, when the one of the name of the brazing alloy and the total volume is determined, the other one will be determined.

A design apparatus for designing a diode connector according to the present invention is characterized in that the diode connector includes a plurality of lead frames having a joint and a terminal formed integrally with the joint; at least one diode chip arranged on the joint of at least one of the plurality of lead frames; a bridge connecting between the diode chip and the joint of at least other one of the plurality of lead frames; and a solder welding the joint of the lead frame, the diode chip and the bridge to each other, and the design apparatus includes a memory device storing melting point data of a plurality of brazing alloys, correlation data between a total volume of the lead frames and the bridge, and heating temperature of the diode chip, a component name of the diode connector and total-volume limitation data about a maximum allowable value of the total volume corresponding to the diode connecter specified by the component name; an input device for inputting a name of the brazing alloy to be used selected from the plurality of brazing alloys and the component name of the diode connector; and a determination device for determining a maximum value and a minimum value of the total volume based on the name of the brazing alloy, the component name of the diode connector, which are inputted into the input device, the melting point data, the correlation data and total-volume limitation data which are stored in the memory device.

According to the present invention mentioned above, the memory device has the melting point data of the plurality of brazing alloys for a solder, and the correlation data between the total volume of the lead frames and the bridge, and heating temperature of the diode chip. Therefore, by corresponding the melting point data and the heat temperature, a relation between the name of the brazing alloy and the required total volume (that is the minimum value of the total volume) when using the brazing alloy can be given. Additionally, the memory device has the component name of the diode connector and the total-volume limitation data about the maximum allowable value of the total volume corresponding to the diode connecter specified by the component name. Therefore, the maximum value corresponding to the component name can be given from the component name.

The design apparatus for designing a diode connector mentioned above present invention is further characterized in that the memory device stores a plurality of the correlation data different from each other and defined corresponding to each one of a type of the diode chips.

According to the present invention mentioned above, the memory device has the plurality of the correlation data different from each other. Thereby, the diode connectors can be designed so as to have different relations from each other of the total volume of the lead frame and the bridge, and heat temperatures of the diode chips.

The design apparatus for designing a diode connector mentioned above present invention is further characterized in that the correlation data is defined by a formula: Td=h*V+a; herein Td is the heating temperature of the diode chip, and h is a temperature coefficient indicating changing ratio of the heating temperature of the diode chip against change of the total volume, and V is the total volume, and a is a temperature constant to be different from each diode chip.

According to the present invention mentioned above, the correlation data is shown in a linear function defined above formula. Thereby, by assigning the one of the total volume V and the heat temperatures Td, the other thereof can be calculated.

A design method of designing a diode connector according to the present invention is characterized in that the diode connector includes a plurality of lead frames having a joint and a terminal formed integrally with the joint; at least one diode chip arranged on the joint of at least one of the plurality of lead frames; a bridge connecting between the diode chip and the joint of at least other one of the plurality of lead frames; and a solder welding the joint of the lead frame, the diode chip and the bridge to each other, and the design method includes the steps of: storing melting point data of a plurality of brazing alloys, and correlation data between a total volume of the lead frames and the bridge, and heating temperature of the diode chip; selecting one of a name of the brazing alloy to be used selected from the plurality of brazing alloys and the total volume; and determining the other one of the name of the brazing alloy and the total volume based on the one of the name of the brazing alloy and the total volume, which is selected, and the melting point data and correlation data, which are stored.

According to the present invention mentioned above, when the one of the name of the brazing alloy and the total volume is determined, the other one of the name of the brazing alloy and the total volume is determined based on the determined one, the melting point data and the correlation data. In other words, the relation of the name of the brazing alloy and the total volume can be given by the meting point data and the correlation data, so that when the one of the name of the brazing alloy and the total volume is determined, the other one will be determined.

A design method of designing a diode connector according to the present invention is characterized in that the diode connector includes a plurality of lead frames having a joint and a terminal formed integrally with the joint; at least one diode chip arranged on the joint of at least one of the plurality of lead frames; a bridge connecting between the diode chip and the joint of at least other one of the plurality of lead frames; and a solder welding the joint of the lead frame, the diode chip and the bridge to each other, and the design method includes the steps of: storing melting point data of a plurality of brazing alloys, correlation data between a total volume of the lead frames and the bridge, and heating temperature of the diode chip, a component name of the diode connector and total-volume limitation data about a maximum allowable value of the total volume corresponding to the diode connecter specified by the component name; inputting a name of the brazing alloy to be used selected from the plurality of brazing alloys and the component name of the diode connector; and determining a maximum value and a minimum value of the total volume based on the name of the brazing alloy, the component name of the diode connector, which are inputted into the input device, the melting point data, the correlation data and total-volume limitation data which are stored in the memory device.

According to the present invention mentioned above, when the one of the name of the brazing alloy and the component name of the diode connector is determined, the required total volume (that is the minimum value of the total volume) is determined based on the name of the brazing alloy, the melting point data, and the correlation data. The maximum allowable value of the total volume is determined based on the component name of the diode connecter and the total-volume limitation data.

A diode connector according to the present invention is characterized in that the diode connector includes a plurality of lead frames having a joint and a terminal formed integrally with the joint; at least one diode chip arranged on the joint of at least one of the plurality of lead frames; a bridge connecting between the diode chip and the joint of at least other one of the plurality of lead frames; and a solder welding the joint of the lead frame, the diode chip and the bridge to each other, and a relation defined by a formula: Ts≧h*V+a; herein Ts is a melting point of the solder, and V is a total volume of the lead frames and the bridge, and h is a temperature coefficient indicating changing ratio of the heating temperature of the diode chip against change of the total volume, and a is a temperature constant to be different from each diode chip: is fulfilled.

According to the present invention mentioned above, the heat temperature of the diode chip corresponding to the total volume of the lead frames and the bridge is not larger than the melting point of the solder. Therefore, the heat temperature does not over the melting point of the solder, so that the solder is not melted.

The diode connector mentioned above invention is further characterized in that the diode connector includes a package arranging the joint and the bridge of the plurality of lead frames inside the package and exposing the terminals of the plurality of lead frames from the package, and the one diode is arranged in the package and a chip size of the one diode is 2.3 mm square, and the total volume of the lead frames and the bridge is not less than 107 mm cubic and not more than 243 mm cubic, when upper limits of outer dimensions of the package are 9.5 mm depth, 7.8 mm width, 5.2 mm height.

The diode connector mentioned above invention further characterized in that the diode connector includes a package arranging the joint and the bridge of the plurality of lead frames inside the package and exposing the terminals of the plurality of lead frames from the package, and two diodes are arranged in the package and each chip size of the two diodes is 2.3 mm square, and the total volume of the lead frames and the bridge is not less than 98.2 mm cubic and not more than 386 mm cubic, when upper limits of outer dimensions of the package are 9.5 mm depth, 11.8 mm width, 5.2 mm height.

The diode connector mentioned above invention is further characterized in that the diode connector includes a package arranging the joint and the bridge of the plurality of lead frames inside the package and exposing the terminals of the plurality of lead frames from the package, and three diode are arranged in the package and each chip size of the diodes is 2.3 mm square, and the total volume of the lead frames and the bridge is not less than 135 mm cubic and not more than 528 mm cubic, when upper limits of outer dimensions of the package are 9.5 mm depth, 15.8 mm width, 5.2 mm height.

The diode connector mentioned above invention is further characterized in that the diode connector includes a package arranging the joint and the bridge of the plurality of lead frames inside the package and exposing the terminals of the plurality of lead frames from the package, and one diode is arranged in the package and a chip size of the one diode is 2.9 mm square, and the total volume of the lead frames and the bridge is not less than 138 mm cubic and not more than 308 mm cubic, when upper limits of outer dimensions of the package are 11.8 mm depth, 7.8 mm width, 5.2 mm height.

### Effects of Invention

According to the present invention mentioned above, based one the melting point data and the correlation data stored in the memory device, the relation between the name of the brazing alloy and the required total volume when using the brazing alloy can be given. Thereby, when the one of the name of the brazing alloy and the total volume is inputted from the input device, the other one of the name of the brazing alloy and the total volume can be determined based on the inputted one and the melting point data and the correlation data. Therefore, the name of the brazing alloy and the total volume can be determined easily and suitably, so that design cost and material cost can be reduced. Especially, by using the correlation data based on an allowable overcurrent, the diode connector can be designed to have the necessary minimum value of the total volume usable under the allowable overcurrent.

According to the present invention mentioned above, the memory device has the melting point data, the correlation data, and the total-volume limitation data, so that, when the name of the brazing alloy and the component name of the diode connector are inputted from the input device, the required total volume, that is the minimum value of the total volume, can be given based on the name of the brazing alloy, the melting point data, and the correlation data. Additionally, the maximum allowable value, that is the maximum value of the total volume, can be given based on the component name of the diode connector and the total-volume limitation data. Thereby, the minimum value and the maximum vale of the total volume of the lead frame and the bridge of the diode connector can be given previously. By determining the total volume to be within a range defined by the maximum value and the minimum value, the diode connector can be designed so as to fulfill a limitation of the total volume (that is the outer dimensions) thereof without melting the solder. Especially, by using the correlation data based on an allowable overcurrent, the diode connector can be designed to be usable under the allowable overcurrent.

According to the present invention mentioned above, the diode connectors can be designed to have different relations of the total volumes of the lead frame and the bridge, and heat temperatures of the diode chips. Thereby, when the correlation data different for each diode chip exist, the diode connectors can be designed to use each diode chip, so that many various diode connector can be designed. When the diode connector cannot be designed to fulfill the correlation of the diode chip, that is the relation between the heat temperature of the diode chip and the total volume of the lead frame and the bridge, the other diode connector can be designed by using the other diode chip instead of the diode chip. Thus, by replacing the diode chip, the diode connector can be applied for a wide condition, so that the diode connector under a tight requirement, such as outer dimensions, can be designed easily.

According to the present invention mentioned above, the correlation data is shown in a linear function, and by assigning the one of the total volume of the lead frame and the bridge, and the heat temperature of the diode chip, the other thereof can be easily calculated. Thereby, the total volume against the heat temperature or the heat temperature against the total volume can be easily and suitably calculated.

According to the present invention mentioned above, when the one of the name of the brazing alloy and the total volume is inputted, the other one of the name of the brazing alloy and the total volume can be determined based on the inputted one, the melting point data and the correlation data. Thereby, the name of the brazing alloy and the total volume can be determined easily and suitably, and design cost and material cost can be reduced. Especially, by using the correlation data based on an allowable overcurrent, the diode connector can be designed to have necessary minimum value of the total volume usable under the allowable overcurrent.

According to the present invention mentioned above, when the name of the brazing alloy and the component name of the diode connector are determined, the required total volume (that is the minimum value of the total volume) is determined based on the name of the brazing alloy, the melting point data, and the correlation data, and the maximum allowable value of the total volume is determined based on the component name of the diode connecter and the total-volume limitation data. Thereby, the minimum value and the maximum value of the total volume of the lead frame and the bridge can be given previously, so that, by determining the total volume within the range defined by the maximum value and the minimum value, the diode connector can be easily designed so as to fulfill a limitation of the total volume (that is the outer dimensions) thereof without melting the solder. Especially, by using the correlation data based on an allowable overcurrent, the diode connector can be designed to be usable under the allowable overcurrent.

According to the present invention mentioned above, the heat temperature of the diode chip does not rise over the melting point of the solder. Thereby, it can be securely prevent that brazing between the diode chip, the lead frame and the bridge by the solder is removed by the head of the diode chip. Therefore, reliability of the diode connector can be improved. Structuring the diode chip, the lead frame, the bridge and the solder so as to make the heat temperature and the melting point of the solder to be equal, the total volume of the lead frame and the bridge can be minimized, and the material cost of the diode connector can be reduced. the heat of the diode chip corresponding to the total volume. Especially, determining the temperature coefficient “h” and the temperature constant “a” in the above formula (2) showing the relation of the total volume “V” and the melting point “Ts” based on the allowable overcurrent, the small diode connector usable under the allowable overcurrent can be designed.

According to the present invention mentioned above, the minimum value and the maximum value of the total volume of the lead frame and the bridge are defined, so that, by determining the total volume of the lead frame and the bridge to be within the range defined by the minimum value and the maximum value, the diode connector can be designed to fulfill the limitation of the outer dimensions without melting the solder by flowing electric current.

The above and other objects and features of this invention will become more apparent from the following description taken in conjunction with the accompanying drawings.

### BRIEF DESCRIPTION OF THE DRAWINGS

FIG. 1 is a block diagram of an embodiment of a design apparatus for designing a diode connector according to the present invention,

FIG. 2 is a perspective view of an embodiment of the diode connector according to the present invention,

FIG. 3 is an exploded perspective view of the diode connector shown in FIG. 2,

FIG. 4 is a sectional view taken along the line IV-IV in FIG. 2,

FIG. 5 is a table of a melting point data showing lead-free brazing alloys and melting points corresponding to each of the brazing alloys,

FIG. 6 is a correlation graph of a total volume and a heat temperature of a diode chip,

FIG. 7 is a flowchart of a process executed by a CPU of the design apparatus of a first embodiment according to the present invention,

FIG. 8 is a flowchart of a process executed by a CPU of the design apparatus of a second embodiment according to the present invention,

FIG. 9 is a block diagram of a measurement structure for measuring relation of a total volume of a lead frame and a bridge, and a heat temperature of the diode chip,

FIG. 10 is a table showing the maximum temperatures when an allowable overcurrent flows each of diode connectors having a different chip size of the diode chip and a different total volume,

FIG. 11 is a block diagram of a third embodiment of the design apparatus according to the present invention,

FIG. 12 is a table of a total-volume limit data showing a component name of the diode connector and an allowable maximum value of the total volume corresponding to the component name,

FIG. 13 is a flowchart of a process executed by a CPU of the design apparatus of a third embodiment according to the present invention,

FIG. 14 is a perspective view of the diode connector with one diode chip and two electrodes designed by the design apparatus according to the present invention,

FIG. 15 is a perspective view of the diode connector with two diode chips and three electrodes designed by the design apparatus according to the present invention,

FIG. 16 is a perspective view of the diode connector with three diode chips and four electrodes designed by the design apparatus according to the present invention,

FIG. 17 is a perspective view of the diode connector with one diode chip and two electrodes designed by the design apparatus according to the present invention,

FIG. 18 is a correlation graph of a total volume of the lead frames and the bridge, and a heat temperature of diode chips of the diode connector with two diode chips and three electrodes shown in FIG. 15, and

FIG. 19 is a correlation graph of a total volume of the lead frames and the bridge, and a heat temperature of diode chips of the diode connector with three diode chips and four electrodes shown in FIG. 16.

### DESCRIPTION OF THE PREFERRED EMBODIMENT

An embodiment of a diode connector according to the present invention is shown with reference to FIGS. 2-4 as follows.

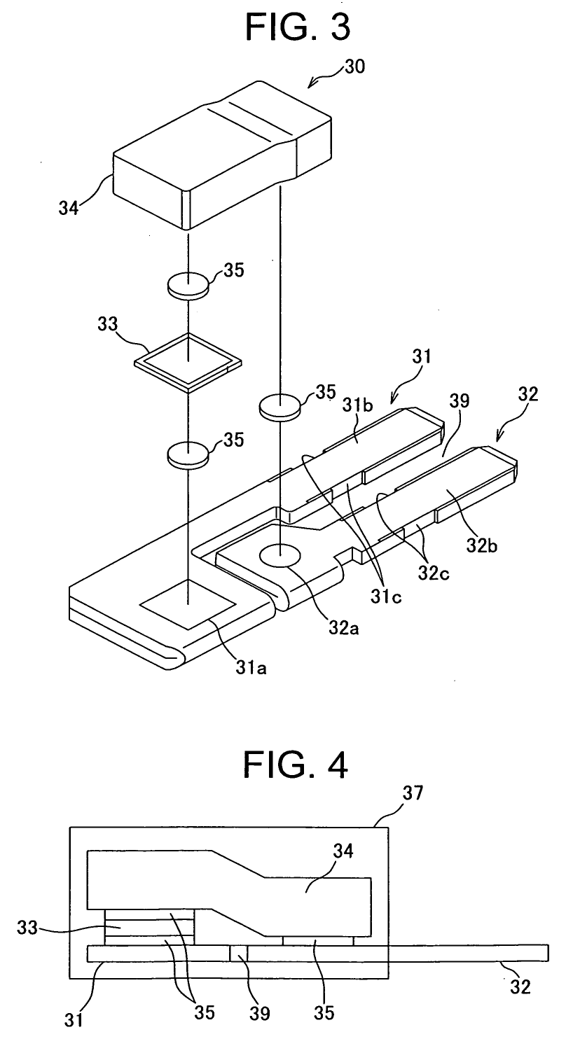

The diode connector 30, as shown in FIG. 2, includes a cathode-side lead frame 31, a anode-side lead frame 32, a diode chip 33, a bridge 34 and a package 37. A shown in FIG. 3, the cathode-side lead frame 31 and the diode chip 33, the diode chip 33 and the bridge 34, the bridge 34 and the anode-side lead frame 32 are brazed by solder 35 to each other.

The cathode-side lead frame 31 is a terminal which is formed into an L-shape by punching copper alloy sheet of around 0.64 mm thick and plating on its surface with silver. At a shorter side of the L-shape, a joint 31a, which has a size larger than the chip size of the diode chip 33, is arranged as an electrode for mounting the diode chip 33. At a longer side of the L-shape, a terminal 31b for connecting to a connector socket (not shown) is arranged.

The terminal 31b is chamfered at each corner thereof for inserting it smoothly into the connector socket. Additionally, a recess 31c engaging with the connector socket is provided at each one of side edges opposing to each other along a widthwise of the terminal 31b for preventing fall-out of the diode connector 30 inserted in the connector socket.

The anode-side lead frame 32 is a terminal which is formed into an I-shape by punching copper alloy sheet of around 0.64 mm thick and plating on its surface with silver. At a one end thereof, a joint 32a having a round shape is arranged as an electrode for mounting the bridge 34. At the other end thereof, a terminal 32b for connecting to a connector socket (not shown) is arranged. The anode-side lead frame 32 is arranged at a right-angle side of the L-shape of the cathode-side lead frame 31 through a gap 39 in parallel to the terminal 31b.

The terminal 32b is chamfered at each corner thereof similarly as the terminal 31b of the cathode-side lead frame 31 for inserting it smoothly into the connector socket. Additionally, a recess 32c engaging with the connector socket is provided at each one of side edges opposing to each other along a widthwise of the terminal 32b for preventing fall-out of the diode connector 30 inserted in the connector socket.

The diode chip 33 is structured with a silicon substrate, an anode-side electrode and a cathode-side electrode. The silicon substrate is formed an oxidized layer on a thin-thick N-type semiconductor and provided with a P-type semiconductor area at an area, in which the oxidized layer is removed, on the N-type semiconductor. The anode-side electrode is arranged to connect with the P-type semiconductor area on the silicon substrate. The cathode-side electrode is arranged to connect with the N-type semiconductor of the silicon substrate. The diode chip 33 is a conventional semiconductor discrete component for flowing electric current in one way. The cathode-side electrode is joined to the joint 31a of the cathode-side lead frame 31, and the anode-side electrode is joined to one end of the bridge 34.

When the current flows in the diode chip 33, a voltage drop of 0.8-0.9 V occurs in a forward direction, and a power loss corresponding to the voltage drop generates heat. The heat property of the diode chip 33 by current flow depends on each chip size (correspond to a type of diode chip) and a total volume of the lead frames 31, 32 and the bridge 34 which are joined with the diode chip 33. The heat property depends on number of diode chips mounted in the diode connector (correspond to the type of the diode chip).

The bridge 34 is a metallic piece formed into a rectangular parallelopiped shape with a metal material (including alloy) having high electric conductivity and high heat conductivity, such as copper or aluminum, for connecting the lead frame. The bridge 34 is provided with a step for canceling a thickness of the diode chip 33. One end of the bridge 34 is joined with the anode-side electrode of the diode chip 33, and the other end of the bride 34 is joined with the joint 32a of the anode-side lead frame 32. Thus, the bridge 34 connects the cathode-side lead frame 31 and the anode-side lead frame 32 through the diode chip 33. The bridge 34 is received and arranged in the package 37 for preventing short of the cathode-side lead frame 31 and the anode-side lead frame.

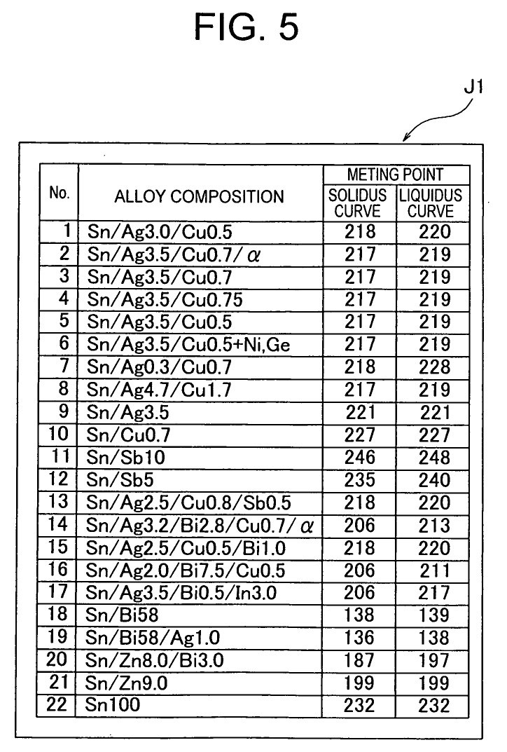

The solder 35 is one of the name of brazing alloys for welding metals to each other and has high electric conductivity for using in a electric circuit. The solder 35 used in the embodiment includes no lead (a lead-free type solder), and is selected based on a melting point data J1 showing a name of lead-free brazing alloys and melting points of the brazing alloys, shown in FIG. 5. When assembling the diode connector 30, the solder 35 is paste including flux and is applied on the joint 31a of the cathode-side lead frame 31, the joint 32a of the anode-side lead frame 32, and the anode-side electrode of the diode chip 33. The lead frames 31, 32, the diode chip 33 and the bridge 34 are assembled so as to overlap each joint, and passed through a reflow chamber, so that the solder 35 is melted and these components are joined to each other.

The package 37 is formed integrally with a heat resisting and electric insulating synthetic resin by a transfer molding method. The package 37 arranges the bridge 37, an end portion including the joint 31a of the cathode-side lead frame 31, and an end portion including the joint 32a of the anode-side lead frame 32 therein for protecting and insulating them arranged therein. The terminal 31b of the cathode-side lead frame 31 and the terminal 32a of the anode-side lead frame 32 project from the package 37 so as to be inserted into the connector socket (not shown). Outer dimensions of the package 37 are determined under a limitation of a place where the diode connector is mounted, for example, a limitation of a space for wiring a wiring harness in a car.

The cathode-side lead frame 31, the anode-side lead frame 32 and the bridge 34 perform as a connecting component for connecting electrically the wiring harness and also as a heat-dissipation component for dissipating heat generated at the diode chip 33 by current flow. Not to melt the solder 35 contacting with the diode chip 33, that is the solder 35 brazing the cathode-side lead frame 31 and the diode chip 33, and the solder 35 brazing the diode chip 33 and the bridge 34 by heat of the diode chip 33, the total-volume is determined.

In the embodiment, a relation between the total volume V, the chip size of the diode chip 33 and the melting point of the solder 35 Ts satisfy the following formulas:

Ts=(−1.4)*V+425[for diode chip of 1.8 mm square] (A)

Ts=(−1.4)*V+340[for diode chip of 2.3 mm square] (B)

Ts=(−1.4)*V+320[for diode chip of 2.9 mm square] (C)

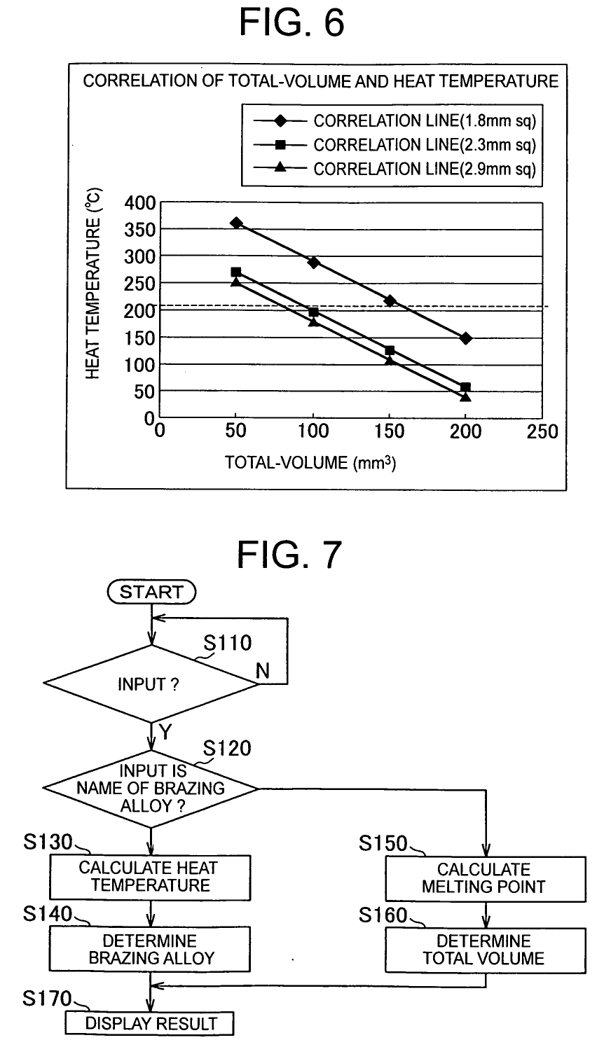

The above formulas (A)-(C) are correlation formulas given from a correlation graph (FIG. 6) of a relation of the total volume and the heat temperature of the diode chip measured for each chip size of the diode chip 33, that is correlation data (describing a measuring method later).

Right hand sides of the above formulas (A)-(C) show heat temperatures of the diode chip 33 generated by flowing predetermined allowable overcurrent (later-described) through the diode connector 30. Left hand sides of the above formulas (A)-(C) show the melting points of the brazing alloys to be used as the solder 35 (more exactly, slightly low temperature than the melting point. Thus, by determining the total volume so as to make the heat temperature of the diode chip 33 (right hand side) and the melting point of the brazing alloy (solder 35) (left hand side) equal, melting of the solder 35 by the heat of the diode chip 33 is prevented, so that it is prevented that the connection of the cathode-side flame 31 and the bridge 34 is removed. Additionally, the diode connector 30 having necessary minimum value can be provided.

The predetermined allowable overcurrent is a current value over a rated current, which can flow the diode connector 30 to maintain functions without malfunctions (especially melting the solder 35). The value, for example, is determined based on pre-arcing time/current characteristics of a fuse arranged in a circuit where the diode connector 30 is mounted. For example, values of the allowable overcurrent of the diode connector 30 in a circuit, in which a fuse of rated current 10 A is arranged, are set at 20A/6 sec, 30A/3 sec, 40A/1 sec, and 60A/0.5 sec.

A combination of the total volume, the chip size of the diode chip 33 and the solder 35 is shown as an example: the chip size of the diode chip 33 of 1.8 mm square, the total volume of 148 mm cubic and the name of the solder 35 of Sn/Ag3.0/Cu0.5 (the melting point of 218° C.). This condition fulfils the above formula (A). The other solder having the melting point of 218° C. or more can be applied for the diode connector 30.

According to the embodiment, the diode connector 30 fulfils one of the above formulas (A)-(C) about the total volume, the chip size of the diode chip 33 and the melting point of the solder 35. Thereby, when allowable overcurrent flows, it is prevented that the solder 35 is melted by the heat of the diode chip 33. Thus, connections of the diode chip 33, the cathode-side lead frame 31 and the bridge 34 are not removed, so that high-reliable diode connector 30 can be provided.

Determining the total volume, the chip size of the diode chip 33 and the solder 35 so as to equalize the right hand sides of the above formulas (A)-(C) and the left hand sides of the above formulas (A)-(C), the diode connector 30, which fulfils required heat dissipation of the diode chip 33, can be provided by the necessary minimum value of the total volume. Therefore, material cost of the diode connector can be reduced.

According to the embodiment, the total volume, the chip size of the diode chip 33 and the name of the solder 35 are determined so as to equalize the right hand sides of the above formulas (A)-(C) and the left hand sides of the above formulas (A)-(C). The condition can be determined so as not to make the right hand side over the left hand side, that is not to make the heat temperature of the diode chip 33 over the melting point of the solder 35. Thus, the heat temperature of the diode chip 33 can be made not higher than the melting point of the solder 35, so that the diode connector can be designed to have a margin of the heat temperature against the melting point of the solder 35.

The diode connector mentioned above includes a pair of the lead frames. It is not limited, and the diode connector can include three or more lead frames or more. The bridge is arranged to straddle between the pair of lead frames. It is not limited, and the bridge can straddle across three or more lead frames, or the diode connector can have bridges, each one of which straddles each two lead frames. The diode connector also can include a plurality of diode chips. The diode chip can have another chip size rather than 1.8 mm square, 2.3 mm square and 2.9 mm square. The correlation formula for each condition should be given.

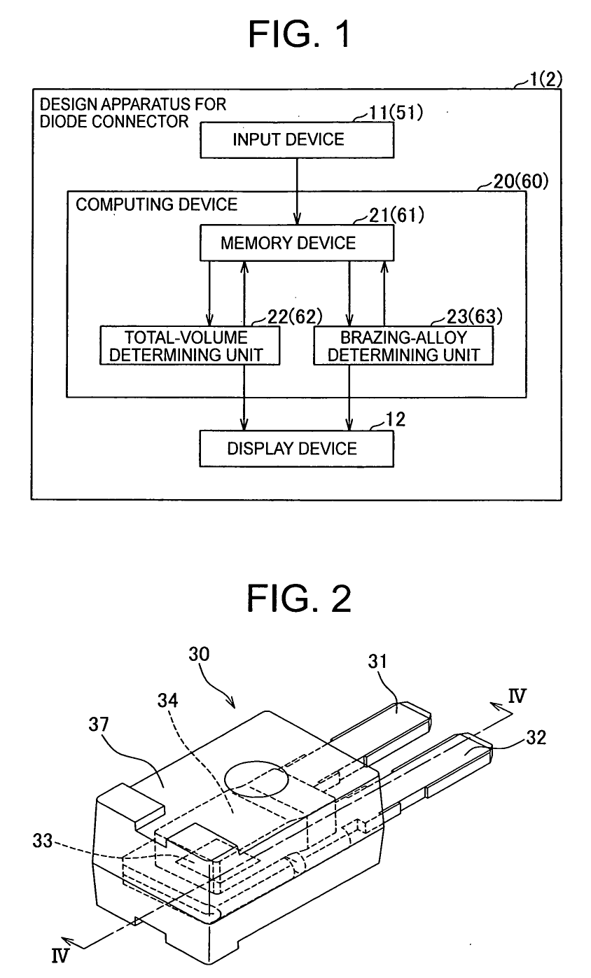

A first embodiment of a design apparatus for designing a diode connector according to the present invention will be shown with reference to FIG. 1, and FIGS. 5-7.

FIG. 1 shows a block diagram of the design apparatus for designing the diode connector. The design apparatus for designing diode connector 1 is an apparatus for designing the diode connector 30 including the cathode-side lead frame 31, the anode-side lead frame 32, the bridge 34 connecting the diode chip 33 and the anode-side lead frame 32 and the solder 35 brazing the lead frames 31, 32, the diode chip 33 and the bridge 34 to each other. When one of the name of brazing alloys used as the solder 35 and the total volume of the lead frames 31, 32 and the bridge 34 is inputted, the design apparatus 1 determines the other of the name of brazing alloys and the total volume, based on the input data, the melting point data J1, stored previously, about each melting point of the plurality of brazing alloys used as the solder 35, and the correlation data, stored previously, between the total volume and the heat temperature of the diode chip 33.

The design apparatus 1 includes an input device 11, a computing device 20 and a display device 12 as shown in FIG. 1.

The input device 11 is used to input one of the name of brazing alloys used as the solder 35 and the total volume into the computing device 20. The name of the brazing alloys is selected from lead-free brazing alloys shown in FIG. 5. The melting point data about the melting points of the brazing alloys also are shown in FIG. 5. Input of the name of the brazing alloys is done by inputting a number corresponding to the name of the brazing alloys. Input of the total volume is done by inputting a numerical value of the total volume. The numerical value is the sum of each volume of the lead frames 31, 32 and the bride 34. Instead, each numerical number of the each volume of lead frames 31, 32 and the bridge 34 can be inputted respectively and the inputted numbers can be summed in the computing device 20.

The input device 11 is used for acting various operations of the design apparatus 1. A well-known keyboard, a mouse, various switches and operation buttons can be used as the input device 11. Instead, it is allowed that one of the name of the brazing alloys and the total volume is stored as electronic data in a hard disc drive, a CD-ROM drive or the other memory device, and the electronic data is read from the device and inputted into the computing device 20.

The computing device 20 is a computer having a CPU (central processing unit), a ROM (read-only memory) and a RAM (random access memory). The computing device 20 has a memory device 21 and a total-volume determining unit 22 and a brazing-alloy determining unit 23, as a determination device.

The memory device 21 stores a program for operating the design apparatus 1. The memory device 21 stores temporarily the name of the brazing alloy or the total volume inputted from the input device 11. The memory device 21 previously stores the name of lead-free brazing alloys and the melting point data about melting points of the brazing alloys. The melting point data J1 is to associate alloy compositions corresponding to the name of the brazing alloys, solidus curves showing temperatures in which the brazing alloys start to melt (that is melting points), liquidus curves showing temperatures in which the brazing alloys completely melt and numbers corresponding to the brazing alloys.

The memory device 21 previously stores following correlation function (D) lead from a correlation graph (FIG. 6) between the total volumes and the heat temperatures of the diode chip 33, which are measured about the diode connector 30 including the diode chip 33 having 1.8 mm square chip size:

Td=(−1.4)*V+425[the chip size 1.8 mm square] (D)

herein Td is the melting point of the diode chip, and “V” is the total volume. Actual measuring method will be described later. The correlation function (D) corresponds to correlation data. Such correlation function is applicable for a plurality of diode chips or a chip size other than the above-mentioned chip size. By leading suitably a correlation function for such structure, the diode connector using the diode chip can be designed.

As the memory device 21, the ROM and the RAM mentioned above are used, and a storage device, such as an HDD drive provided in a computer, may be used.

When the name of the brazing alloy is inputted in the input device 11, the total-volume determining unit 22 determines (calculates) the total volume by calculating the melting point corresponding to the brazing alloy, the name of which was inputted, based on the melting point data J1, and applying the calculated melting point of the brazing alloy as the heat temperature of the diode chip 33 to the correlation function (D). Detailed process will be following. Firstly, the melting point of the brazing alloy is led by collating the names of the brazing alloy stored temporarily in the memory device 21 to the melting point data J1. Secondly, applying the melting point of the brazing alloy as the heat temperature of the diode chip 33 to the correlation function (D), the total volume is calculated (determined).

When the total volume is inputted to the input device 11, by applying the inputted total volume to the correlation function (D), and calculating the heat temperature of the diode chip 33, the brazing-alloy determining unit 23 determines the brazing alloy corresponding to the calculated heat temperature of the diode chip 33 as the melting point based on the melting point data J1. Detailed process will be following. Firstly, by applying the total volume stored in the memory device 21 to the correlation function (D), the heat temperature of the diode chip 33 is calculated. Secondly, the brazing alloy having the melting point not less than and closest to the heat temperature of the diode chip 33 is selected (determined) from the melting point data J1.

Above-mentioned functions of the total-volume determining unit 22 and the brazing-alloy determining unit 23 are acted by the computer.

The display device 12 shows operation status of the design apparatus 1, the determined total volume and the determined brazing alloy. As the display device 12, a known CRT (cathode ray tube) display or a liquid crystal display can be used.

One example of processes executed by the computing device 20 is shown with reference to a flowchart in FIG. 7.

When the computing device 20 is supplied electric power, the computing device 20 executes predetermined initializing processes and after that the process proceeds to a step S110. In the step S110, it is judged whether or not inputting one of the name of the brazing alloy and the total volume is acted. In detail, it is confirmed whether or not one of the name of the brazing alloy and the total volume is stored in the memory device 21. When the one of the name of the brazing alloy and the total volume is stored, it is judged that inputting to the input device 11 is acted (Y in S110) and the process proceeds to a step S120. When both of them are not stored, it is judged that inputting to the input device 11 is not acted (N in S110) and the process of S110 is repeated until the inputting is acted.

In the step S120, it is judged which of the name of brazing alloy and the total volume is stored (that is which is inputted from the input device 11) with reference to one from data of the name of the brazing alloys and the total volumes stored in the memory device 21. When the name of the brazing alloy is stored, the process proceeds to a step S150 for determining the total volume (Y in step S120). When the total volume is stored, the process proceeds to a step S130 for determining the brazing alloy (N in step S120).

In the step S130, the heat temperature of the diode chip 33 is calculated by applying the total volume stored in the memory device 21 to the correlation function (D) previously stored in the memory device 21. After calculating, the process proceeds to a step S140.

In the step S140, by collating the heat temperature of the diode chip 33 calculated in the step S130 as the melting point of the brazing alloy to the melting point data J1 previously stored in the memory device 21, the brazing alloy having the melting point not less than and closest to the heat temperature is selected (determined). Thereafter, the process proceeds to a step S170.

In the step S150, by collating the name of the brazing alloy stored in the memory device 21 to the melting point data J1 previously stored in the memory device 21, the melting point of the brazing alloy is led. After that, the process proceeds to a step S160.

In the step S160, by applying the melting point of the brazing alloy led in the step S150 as the heat temperature of the diode chip 33 to the correlation function (D), the total volume is calculated (determined). And, the process proceeds to a step S170.

In the step S170, the brazing alloy selected in the step S140 or the total volume determined in the step S160 is displayed in the display device 21. Thereafter, the process by the flowchart is stopped.

The steps S130, S140 correspond to the brazing alloy detecting unit 23. The steps S150, S160 correspond to the total-volume determining unit 22. The brazing-alloy determining unit 23 and the total-volume determining unit 22 structure the determining device.

One example of an operation for processing determination according to the present invention in the design apparatus 1 for designing the diode connector mentioned above will be described.

In the design apparatus for designing a diode connector 1, when a datum showing a name of the brazing alloy, such as a number “7” indicating the brazing alloy of Sn/Ag 0.3/Cu 0.7, included in the melting point data J1 in FIG. 5 is inputted in the input device 11, the melting point of 218° C. of the brazing alloy is led from the melting point data J1, referring the inputted “7” as index. Applying the melting point of 218° C. as the heat temperature of the diode chip 33 to the correlation function (D), the total volume of 148 mm cubic is calculated. Thereafter, the calculated total volume is shown in the display device 21.

When the total volume of 130 mm cubic is inputted in the input device 11, the design apparatus 1 calculates the heat temperature of 243° C. of the diode chip 33 by applying the inputted total volume to the correlation function (D). By searching the number (name) of the brazing alloy with not less than and closest to the calculated heat temperature in the melting point data J1, in result, the brazing alloy of Sn/Sb10 corresponding to number “11” is selected. Thereafter, the number of the selected brazing alloy and the alloy content are shown in the display device 12.

By determining the total volume corresponding the brazing alloy, or the brazing alloy corresponding the total volume, the diode connector 30 is designed by the design apparatus 1, and heat dissipation test for a trial sample of the designed diode connector is acted. In result, when changes of the total volume and the brazing alloy are required, the one of the total volume and the name of the brazing alloy is inputted in the design apparatus 1, and the other of the total volume and the type of the brazing alloy is determined again. For inputting the one of them again, it is not necessary to input the same one as the previously inputted one of the type of brazing alloy and the total volume, the other of them can be inputted.

As mentioned above, according to the first embodiment, the relation between the brazing alloy and the necessary total volume corresponding to the brazing alloy can be given from the melting point data J1 and the correlation function (D). Thus, when the one of the name of the brazing alloy and the total volume is inputted from the input device 11, the other of the name of the brazing alloy and the total volume can be determined based on the inputted one, the melting point data J1 and the correlation function (D). For example, when the total volume of the lead frames 31, 32 and the bridge 34 used in general diode connector is calculated and inputted in the design apparatus 1, the suitable brazing alloy, that is the solder 35, can be determined and the diode connector commonly using the general components can be designed easily. By commonly using the general components, new tooling for the lead frames 31, 32 and the bridge 34 can be saved and cost down can be led by effect of more volume production. The correlation function (D) is led based on the allowable overcurrent, so that the diode connector having a necessary minimum value of the total volume to be usable under the allowable overcurrent can be designed.

The correlation function (D) can be formed with a linear function. By applying the one of the heat temperature of the diode chip 33 and the total volume of the lead frame and the bridge to the correlation function, the other of them can be calculated. Thereby, the total volume against the heat temperature, or the total volume against the heat temperature can be easily calculated. Thus, the necessary other data against the one data can be easily calculated so that the diode connector can be easily and suitably designed.

By using the correlation function (D) led by actual measured data, the diode connector 30 designed by the design apparatus 1 has heat dissipation performance in actual operation not far from the target design performance. When the actual operation of the diode connector 30 requires, in result, change of the total volume or the brazing alloy, large change is not required, so that the result of the actual operation can be fed back shortly to design process. Thus, design cycle time can be shortened and the design cost can be reduced.

In the first embodiment, the one of the name of the brazing alloy and the total volume is inputted in the input device 11. By inputting the name of the brazing alloy and one of the volumes of the leaf frame and the bridge, the other of the volumes of the leaf frame and the bridge can be calculated by subtracting the inputted one of volumes of the leaf frame and the bridge from the total volume determined based on the name of the brazing alloy, the melting point data J1 and the correlation function (D), and shown as the other of the volumes of the leaf frame and the bridge in the display device 12.

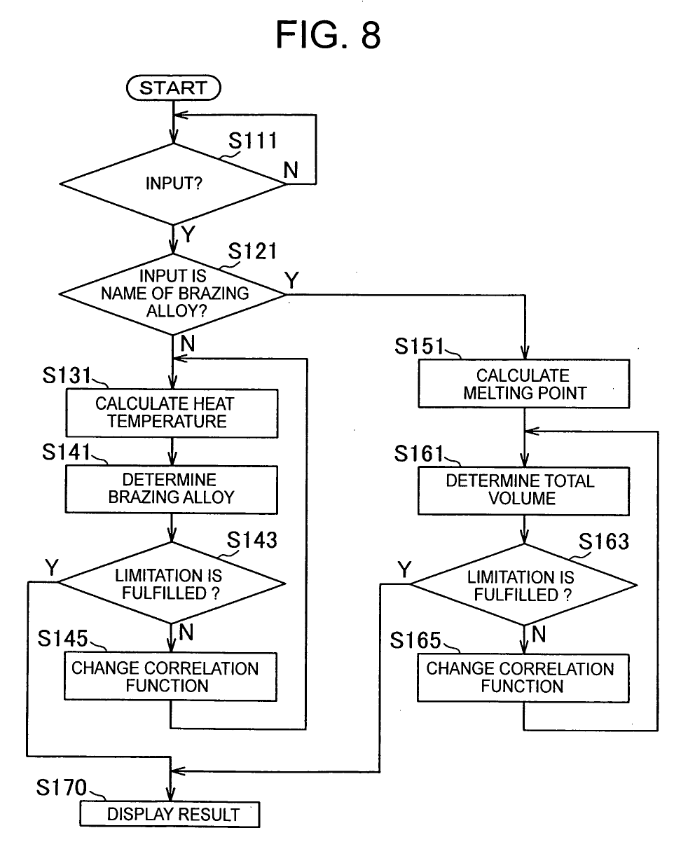

A second embodiment of the design apparatus for designing the diode connector according to the present invention will be described with reference to FIGS. 1 and 8.

A design apparatus 2 for designing a diode connector is an apparatus for designing the diode connector 30 shown in FIG. 2. The design apparatus 2 as shown in FIG. 1 includes an input device 51 and a computing device 60. Regarding display device 12 is the same as that in the first embodiment, so that the description about it is omitted.

The input device 51 is used for inputting one of the name of the brazing alloy as the solder 35 and the total volume, and a limit condition corresponding to the other of them to be determined by the design apparatus 2, into the computing device 60. The limit condition is a condition for determining the brazing alloy and the total volume. Regarding the total volume, the condition is allowable outer dimensions (depth, width, height) of the package 37 of the diode connector 30. Regarding the brazing alloy, the condition is candidates of the brazing alloy selected previously from the melting point data J1 shown in FIG. 5. The input device 51 is the same as the input device 11 in the first embodiment other than that mentioned above, so that the description is omitted.

The computing device 60 is a computer including a known CPU (central processing unit), a ROM (read-only memory) and a RAM (random access memory). The computing device 60 includes a memory device 61, a total-volume determining unit 62 and a brazing-alloy determining unit 63.

The memory device 61 stores a program for operating the design apparatus 2. The memory device 61 stores temporarily the name of the brazing alloy or the total volume and the limit condition inputted from the input device 51.

The memory device 61 previously stores following correlation functions led from a correlation graph (FIG. 6) between the total volumes and the heat temperatures of the diode chip 33, which are measured about each of the diode connectors 30 including the diode chip 33 having different chip size:

Td=(−1.4)*V+425[the chip size 1.8 mm square] (D)

Td=(−1.4)*V+340[the chip size 2.3 mm square] (E)

Td=(−1.4)*V+320[the chip size 2.9 mm square] (F)

herein Td is the melting point of the diode chip, and “V” is the total volume. The correlation function (D) is the same as mentioned above.

The correlation function (D) corresponds to the diode chip 33 having the chip size of 1.8 mm square. The correlation function (E) corresponds to the diode chip 33 having the chip size of 2.3 mm square. The correlation function (F) corresponds to the diode chip 33 having the chip size of 2.9 mm square. These correlation functions correspond to the correlation data different about the chip size of the diode chip. The correlation function is acceptable for the diode connector having a plurality of diode chips or the diode connector having the diode chip other than that mentioned above. By determining suitably the correlation function for the diode connector having such structure, the diode connector using the structure can be designed.

The memory device 61 has an area for storing the correlation function to be used, in which area the correlation function (D) is stored in the initial condition. The memory device 61 also includes an allowable value data for calculating allowable value of the total volume led from the outer dimensions of the package 37 of the diode connector 30. The allowable value data is actually the value of a necessary minimum wall thickness for insulation of the package 37 of the diode connector 30. In this embodiment, the value of 1.0 mm is stored, so that the maximum value (allowable value) of the total volume is calculated by multiplying values, which is led by subtracting the value of the minimum wall thickness 1.0 mm from the outer dimensions (depth, width, height) of the package 37. The value of the wall thickness can be changed for each diode connector 30 to be designed. Instead, a value by multiplying the volume, calculated from the outer dimensions of the package 37, by a certain rate can be used as the allowable value data. The memory device 61 is the same as the memory device 21 in the first embodiment other then that mentioned above, so that the description is omitted.

When the name of the brazing alloy is inputted in the input device 51, the total-volume determining unit 62 determines (calculates) the total volume by calculating the melting point corresponding to the brazing alloy, the name of which was inputted, based on the melting point data J1, and applying the calculated melting point of the brazing alloy as the heat temperature of the diode chip 33 to the correlation function (D). Thereafter, it is judged whether or not the calculated total volume fulfills the limit condition, and when the condition is fulfilled, the process is stopped. When the condition is not fulfilled, the total volume is calculated repeatedly by changing the correlation functions (E), (F) in order until the condition is fulfilled.

The total-volume determining unit 61 acts a following process in detail.

Firstly, the melting point of the brazing alloy is led by collating the names of the brazing alloy stored temporarily in the memory device 61 to the melting point data J1. Secondly, applying the melting point of the brazing alloy as the heat temperature of the diode chip 33 to the correlation function (D), the total volume is calculated (determined). Next, the allowable value of the total volume is calculated by leading the allowable outer dimensions of the package 37 of the diode connector 30 as the limit condition stored temporarily in the memory 61 by using the allowable value data, and compared with the total volume calculated above. When the calculated total volume is smaller than the allowable value, the total volume is determined. When the total volume is larger than the allowable value, changing the correlation function (D) to the correlation function (E), the total volume is calculated again and compared with the allowable value again. When the calculated total volume is smaller than the allowable value, the total volume is determined. When the total volume is larger than the allowable value, changing the correlation function (E) to the correlation function (F), the total volume is calculated again more and compared with the allowable value again more.

When the total volume is inputted to the input device 11, by applying the inputted total volume to the correlation function (D), and calculating the heat temperature of the diode chip 33, the brazing-alloy determining unit 63 determines the brazing alloy corresponding to the calculated heat temperature of the diode chip 33 as the melting point based on the melting point data J1. It is judged whether or not the brazing alloy fulfills the limit condition, and when the limit condition is fulfilled, the process is stopped. When the limit condition is not fulfilled, the correlation function is changed from (D) to (E) and (F) in order, and judging is repeated until the limit condition is fulfilled.

Detailed process in the brazing-alloy determining unit will be following. Firstly, the heat temperature of the diode chip 33 is calculated by applying the total volume stored in the memory device 61 to the correlation function (D). Secondly, the brazing alloy having the melting point not less than and closest to the calculated heat temperature of the diode chip 33 from the melting point data J1. And it is judged whether or not the selected brazing alloy is included in the candidates of the brazing alloys as the limit condition. When the selected brazing alloy is included in the candidates of the brazing alloys, the brazing alloy is determined and the process is stopped. When the selected alloy is not included in the candidates of the brazing alloys, changing from the correlation function (D) to the correlation function (E), and calculating the heat temperature of the diode chip 33 and selecting the brazing alloy, it is judged again whether or not the selected brazing alloy is included in the candidates of the brazing alloys. When the selected brazing alloy is included in the candidates of the brazing alloys, the brazing alloy is determined and the process is stopped. When the selected alloy is not included in the candidates of the brazing alloys, changing from the correlation function (E) to the correlation function (F), and calculating the heat temperature of the diode chip 33 again more, the brazing alloy is selected (determined) again more.

One example of processes executed by the computing device 60 is shown with reference to a flowchart in FIG. 8. The step S170 is the same as that of the first embodiment, so that the description is omitted.

When the computing device 60 is supplied electric power, the computing device 60 executes predetermined initializing processes and after that the process proceeds to a step S111. In the step S111, it is judged whether or not inputting one of the name of the brazing alloy and the total volume, and a limit condition corresponding to the other of them is acted. In detail, it is confirmed whether or not one of the name of the brazing alloy and the total volume is stored in the memory device 61 and also confirmed whether or not the limit condition corresponding to the other in the memory device 61. When the one of the name of the brazing alloy and the total volume and the limit condition are stored, it is judged that inputting to the input device 51 is acted (Y in S111) and the process proceeds to a step S121. When both of the one of the name of the brazing alloy and the total volume and the limit condition are not stored, it is judged that inputting to the input device 51 is not acted (N in S111) and the process of S111 is repeated until the inputting is acted.

In the step S121, it is judged which of the name of brazing alloy and the total volume is stored (that is which is inputted from the input device 51) with reference to one from data of the name of the brazing alloys and the total volumes stored in the memory device 61. When the name of the brazing alloy is stored, the process proceeds to a step S151 for determining the total volume (Y in step S121). When the total volume is stored, the process proceeds to a step S131 for determining the brazing alloy (N in step S121).

In the step S131, referring the area of the correlation function in the memory device 61, and getting data showing the correlation function, based on the data showing the correlation function, the correlation function to be used is selected from the plurality of the correlation functions. Applying the total volume stored in the memory device 61 to the selected correlation function, the heat temperature of the diode chip 33 is calculated. After calculating, the process proceeds to a step S141.

In the step S141, by collating the heat temperature of the diode chip 33 calculated in the step S131 as the melting point of the brazing alloy to the melting point data J1 previously stored in the memory device 61, the brazing alloy having the melting point-not less than and closest to the heat temperature is selected. Thereafter, the process proceeds to a step S143.

In the step S143, it is judged whether or not the limit condition is fulfilled. In detail, it is judged whether or not the brazing alloy determined in the step S141 is included in the candidates of the brazing alloy as the limit condition stored in the memory device 61. When the brazing alloy is included in the candidates, the brazing alloy is determined and the process proceeds to a step S170 (Y in step S143). When the brazing alloy is not included in the candidates, the process proceeds to a step S145 (N in step S143) for changing the correlation function.

In the step S145, the data showing the correlation function stored in the area for storing the correlation function is changed to data showing the correlation function corresponding to diode chip 33 having an uprank chip size. In other words, when the data showing the correlation function (D) is stored, the data is changed to the data showing the correlation function (E). When the data showing the correlation function (E) is stored, the data is changed to the data showing the correlation function (F). Thereafter, the process proceeds to a step S131 for selecting again the brazing alloy.

In the step S151, by collating the brazing alloy stored in the memory device 61 to the melting point data J1 previously stored in the memory device 61, the melting point of the brazing alloy is led. Thereafter, the process proceeds to a step S161.

In the step 161, by referring the area of the correlation function data in the memory device 61, the data showing the correlation function to be used is led, and based on the led data showing the correlation function, the correlation function to be used is selected from the plurality of correlation functions stored in the memory device 61. Thereafter, by applying the melting point of the brazing alloy led in the step S151 as the heat temperature of the diode chip 33 to the selected correlation function, the total volume is calculated. Then, the process proceeds to a step S163.

In the step S163, it is judge whether or not the limit condition is fulfilled. In detail, it is judged whether or not the total volume calculated in the step S161 is not more than the allowable value of the total volume led by applying the allowable value data to the allowable outer dimensions of the package 37 of the diode connector 30 stored in the memory device 61, which volume is by subtracting necessary minimum thickness of 1.0 mm for insulation from the allowable outer dimensions (depth, width, height). When the total volume is not more than the allowable value (Y in step S163), the total volume is determined, and the process proceeds to the step S170. When the total value is more than the allowable value (N in step S163), the process proceeds to a step S165 for changing the correlation function.

In the step S165, the data showing the correlation function stored in the area of correlation function is changed to the data showing the correlation function corresponding to diode chip 33 having the uprank chip size. In other words, when the data showing the correlation function (D) is stored, the data is changed to the data showing the correlation function (E). When the data showing the correlation function (E) is stored, the data is changed to the data showing the correlation function (F). Thereafter, the process proceeds to a step S161 for calculating again the total volume.

The steps S132, S141, S143 and S145 correspond to the brazing-alloy determining unit 63. The steps S151, S161, S163 and S165 correspond to the total-volume determining unit 62. The total-volume determining unit 62 and the brazing-alloy determining unit 63 structure the determining device.

One example of an operation for processing determination according to the present invention in the design apparatus 2 for designing the diode connector mentioned above will be described.

In the design apparatus 2 for designing a diode connector, when data showing the name of the brazing alloy, such as a number “21” indicating the brazing alloy of Sn/Zn 9.0, included in the melting point data J1 in FIG. 5 and the allowable outer dimensions of the package 37 of the diode connector 30 as the limit condition, for example, 6 mm depth, 5.5 mm width, 5 mm height, are inputted in the input device 11, the melting point of 199° C. of the brazing alloy is led from the melting point data J1, referring the inputted “21” as index.

Applying the led melting point of 199° C. as the heat temperature of the diode chip 33 to the correlation function (D), the total volume of 161 mm cubic is calculated. Comparing the calculated total volume of 161 mm cubic and the allowable value of the total volume of 90 mm cubic led from the allowable outer dimensions of the package 37 of the diode connector 30, the calculated total volume is larger, so that the correlation function (D) is changed to the correlation function (E).

By using the correlation function (E), the total volume is calculated again. The total volume becomes 101 mm cubic. Comparing the calculated total volume of 101 mm cubic and the allowable value of the total volume of 90 mm cubic, the calculated total volume is still larger, so that the correlation function (E) is changed to the correlation function (F).

By using the correlation function (F), the total volume is calculated again. The total volume becomes 86 mm cubic. Comparing the calculated total volume of 86 mm cubic and the allowable value of the total volume of 90 mm cubic, the calculated total volume is smaller, so that the total volume is determined. Displaying the determined total volume on the display device, and the process is stopped.

When the total volume of 100 mm cubic and the candidates of the brazing alloy as the limit condition, for example, “number 20, Sn/Zn8.0/Bi3.0” and “number 21, Sn/Zn9.9” are inputted in the input device 51, the design apparatus 2 calculates the heat temperature of 285° C. of the diode chip 33 by applying the inputted total volume to the correlation function (D). The brazing alloy having the melting point not less than the calculated heat temperature is searched in the melting point data J1. In result, there is no brazing alloy corresponding to the condition. Therefore, the correlation function (D) is changed to the correlation function (E).

Next, by using the correlation function (E), the heat temperature of the diode chip 33 is calculated. The calculated heat temperature is 200° C. The brazing alloy having the melting point not less than and closet to the calculated heat temperature is searched in the melting point data J1. In result, the brazing alloys are number 14, 16 and 17 (the melting point 206° C.). It is judge which brazing alloy corresponds to a candidate from the searched brazing alloys. There is no brazing alloy corresponding to the condition. Therefore, the correlation function (E) is changed to the correlation function (F).

Next, by using the correlation function (F), the heat temperature of the diode chip 33 is calculated. The calculated heat temperature is 180° C. The brazing alloy having the melting point not less than and closet to the calculated heat temperature is searched in the melting point data J1. In result, the brazing alloy is number 20 (the melting point 187° C.). It is judge which brazing alloy corresponds to a candidate from the searched brazing alloy. The brazing alloy of number 20 corresponds to the condition. The brazing alloy of number 20 is determined, so that the brazing alloy is shown in the display device 21, and the process is stopped.

By determining the total volume corresponding to the brazing alloy, or the brazing alloy corresponding to the total volume, the diode connector 30 is designed by the design apparatus 2, and heat dissipation test for a trial sample of the designed diode connector is acted. In result, when changes of the total volume and the brazing alloy are required, the one of the total volume and the name of the brazing alloy is inputted in the design apparatus 2, and the other of the total volume and the type of the brazing alloy is determined again. For inputting the one of them again, it is not necessary to input the same one as the previously inputted one of the type of brazing alloy and the total volume, the other of them can be inputted.

As mentioned above, according to the second embodiment, the relation between the brazing alloy and the necessary total volume corresponding to the brazing alloy can be given from the melting point data J1 and the correlation functions (D)-(F) stored in the memory device 61. Thus, when the one of the name of the brazing alloy and the total volume is inputted from the input device 51, the other of the name of the brazing alloy and the total volume can be determined based on the inputted one, the melting point data J1 and the correlation functions (D)-(F). For example, when the total volume of the lead frames 31, 32 and the bridge 34 used in general diode connector is calculated and inputted in the design apparatus 2, the suitable brazing alloy, that is the solder 35, can be determined and the diode connector commonly using the general components can be designed easily. By commonly using the general components, new tooling for the lead frames 31, 32 and the bridge 34 can be saved and cost down can be led by effect of more volume production. Additionally, the allowable outer dimensions of the diode connector 30 or the candidates of the brazing alloys as the limit condition can be inputted, so that the diode connector 30 can designed to fulfill the limit condition. Therefore, the diode connector to fulfill the limit condition can be designed easily. The correlation functions (D)-(F) are led based on the allowable overcurrent, so that the diode connector having a necessary minimum value of the total volume to be usable under the allowable overcurrent can be designed.

The correlation functions (D)-(F) can be formed with a linear function. By applying the one of the heat temperature of the diode chip 33 and the total volume of the lead frame and the bridge to the correlation functions (D)-(F), the other of them can be calculated. Thereby, the total volume against the heat temperature, or the total volume against the heat temperature can be easily calculated. Thus, the necessary other data against the one data can be easily calculated so that the diode connector can be easily and suitably designed.

By storing different correlation function for each chip size of the diode chip, the diode connector using the diode chip having different chip size can be designed, so that the various diode connectors can be provided. When the diode connector designed by using the diode chip 33 having certain chip size does not fulfill the correlation function corresponding to the diode chip 33, the diode chip 33 can be changed to other diode chip having different chip size. Thereby, the diode connector can be designed to correspond to wider condition by changing the diode chip 33. Thus, the diode connector having tight requirement about the outer dimensions can be designed easily.

By using the correlation functions (D)-(F) led by actual measured data, the diode connector 30 designed by the design apparatus 2 has heat dissipation performance in actual operation not far from the target design performance. When the actual operation of the diode connector 30 requires, in result, change of the total volume or the brazing alloy, large change is not required, so that the result of the actual operation can be fed back shortly to design process. Thus, design cycle time can be shortened and the design cost can be reduced.

In the second embodiment, the one of the name of the brazing alloy and the total volume and the limit condition corresponding to each one are inputted in the input device 51. By inputting the name of the brazing alloy and one of the volumes of the leaf frame 31, 32 and the bridge 34, the other of the volumes of the leaf frame and the bridge can be calculated by subtracting the inputted one of volumes of the leaf frame and the bridge from the total volume determined based on the name of the brazing alloy, the melting point data J1 and the correlation functions (D)-(F), and shown as the other of the volumes of the leaf frame and the bridge in the display device 12.

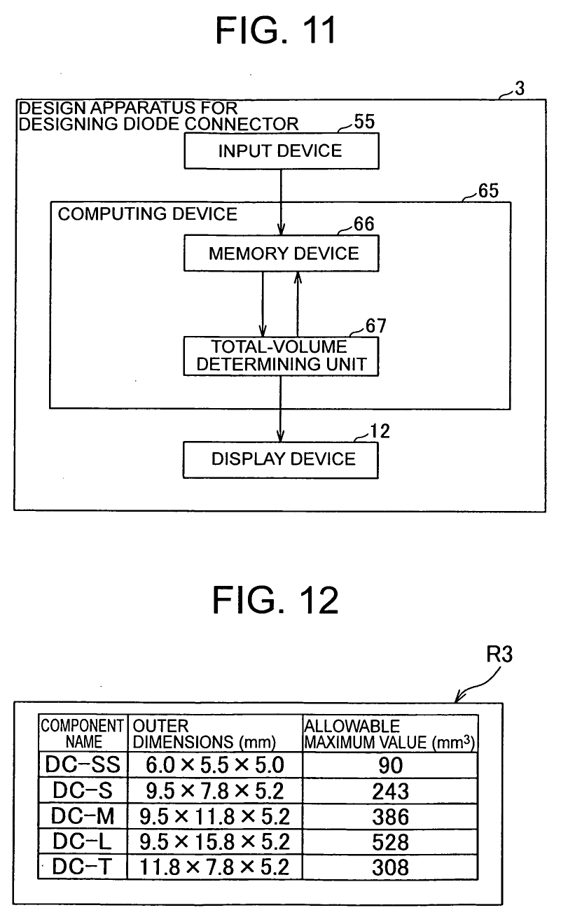

A third embodiment of the design apparatus for designing the diode connector according to the present invention will be described with reference to FIGS. 11-13.

A design apparatus 3 for designing a diode connector is an apparatus for designing the diode connector 30 shown in FIG. 2 as same as the first embodiment, for calculating a minimum value and a maximum value of the total volume of the lead frames 31, 32 and the bridge 34 by inputting the name of the brazing alloy and the component name of the diode connector 30. The design apparatus 3 as shown in FIG. 11 includes an input device 55, a computing device 65 and the display device 12. Regarding display device 12 is the same as that in the first embodiment, so that the description about it is omitted.

The input device 55 is used for inputting the name of the brazing alloy as the solder 35 and the component name of the diode connector 30 into the computing device 65. The component name of the diode connector is assigned to each diode connector having different outer dimensions. The component name corresponds to the maximum value of the total volume allowed for the diode connector 30 (allowable maximum value). The input device 55 is the same as the input device 11 in the first embodiment other than that mentioned above, so that the description is omitted.

The computing device 65 is a computer including a known CPU (central processing unit), a ROM (read-only memory) and a RAM (random access memory). The computing device 65 includes a memory device 66, a total-volume determining unit 67 as the determining device as shown in FIG. 11.

The memory device 66 stores a program for operating the design apparatus 3. The memory device 65 stores temporarily the name of the brazing alloy and the component name of the diode connector 30 inputted from the input device 55.

The memory device 66 previously stores following correlation functions led from a correlation graph (FIG. 6) between the total volumes and the heat temperatures of the diode chip 33, which are measured about each of the diode connectors 30 including the diode chip 33 having different chip size:

Td=(−1.4)*V+425[the chip size 1.8 mm square] (D)

Td=(−1.4)*V+340[the chip size 2.3 mm square] (E)

Td=(−1.4)*V+320[the chip size 2.9 mm square] (F)

herein Td is the melting point of the diode chip, and “V” is the total volume. The correlation functions (D)-(F) are the same as mentioned above.

The correlation function (D) corresponds to the diode chip 33 having the chip size of 1.8 mm square. The correlation function (E) corresponds to the diode chip 33 having the chip size of 2.3 mm square. The correlation function (F) corresponds to the diode chip 33 having the chip size of 2.9 mm square. These correlation functions correspond to the correlation data different about the chip size of the diode chip. The correlation function is acceptable for the diode connector having a plurality of diode chips or the diode connector having the diode chip other than that mentioned above. By determining suitably the correlation function for the diode connector having such structure, the diode connector using the structure can be designed.

The memory device 66 has an area for storing the correlation function to be used, in which area the correlation function (D) is stored in the initial condition. The memory device 66 also stores a total-volume limit data R3 shown in FIG. 12. The total-volume limit data R3 links the component name of the diode connector and the allowable maximum value of the total volume calculated previously about the diode connector having the component name. The allowable value of the total volume is calculated by multiplying values, which is led by subtracting the value of the minimum wall thickness, for example 1.0 mm, for insulation from the outer dimensions (depth, width, height) of the package 37 of the diode connector, to each other, or by multiplying the volume, calculated from the outer dimensions of the package 37, by a certain rate. The memory device 66 is the same as the memory device 21 in the first embodiment other then that mentioned above, so that the description is omitted.

When the name of the brazing alloy is inputted in the input device 55, the total-volume determining unit 67 calculates (determines) the total volume by calculating the melting point corresponding to the brazing alloy, the name of which was inputted, based on the melting point data J1, and applying the calculated melting point of the brazing alloy as the heat temperature of the diode chip 33 to the correlation function (D). And the allowable maximum value of the total volume is calculated based on the component name of the diode connector 30 inputted in the input device 55 and the total-volume limit data R3. Thereafter, it is judged whether or not the calculated total volume is not more that the allowable maximum value, and when the calculated total volume is not larger than the allowable maximum value, the process is stopped. When the calculated total volume is larger than the allowable maximum value, the total volume is calculated repeatedly by changing the correlation functions (E), (F) in order until the calculated total volume becomes not larger than the allowable maximum value. Instead, when the chip size of the diode chip 33 and number of the diode chips are predetermined, the total volume can be calculated by using only the correlation function corresponding to them.

The total-volume determining unit 67 acts a following process in detail.

Firstly, the melting point of the brazing alloy is led by collating the names of the brazing alloy stored temporarily in the memory device 66 to the melting point data J1. Secondly, applying the melting point of the brazing alloy as the heat temperature of the diode chip 33 to the correlation function (D), the total volume is calculated. Next, the allowable maximum value of the total volume for the component name of the diode connector 30 stored temporarily in the memory device 66 is led by using the total-volume limit data. And the allowable value and the calculated total volume are compared. When the calculated total volume is not larger than the allowable value, the total volume is determined. When the total volume is larger than the allowable value, changing the correlation function (D) to the correlation function (E), the total volume is calculated again and compared with the allowable value again. When the calculated total volume is not larger than the allowable value, the total volume is determined. When the total volume is larger than the allowable value, changing the correlation function (E) to the correlation function (F), the total volume is calculated again more.

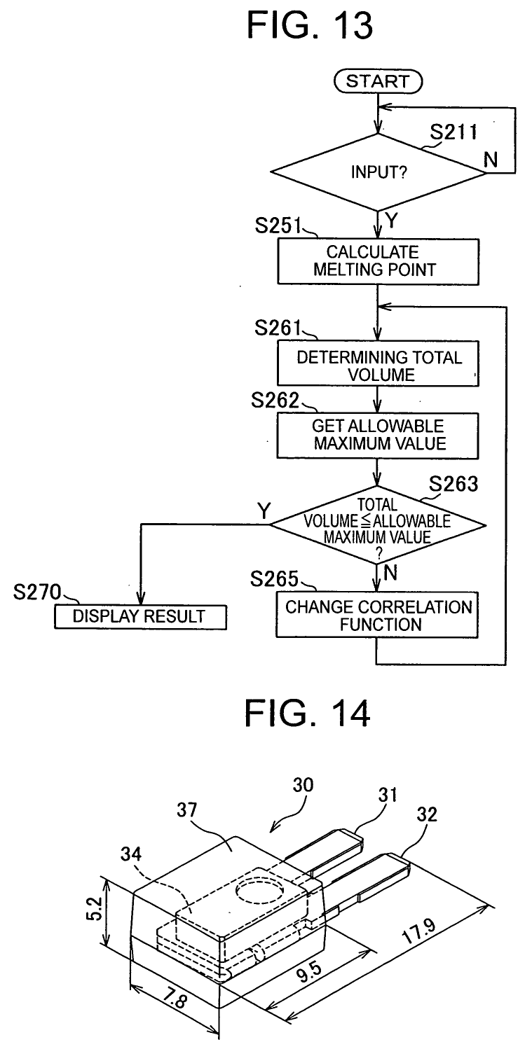

One example of processes executed by the computing device 65 is shown with reference to a flowchart in FIG. 13.

When the computing device 65 is supplied electric power, the computing device 65 executes predetermined initializing processes and after that the process proceeds to a step S211. In the step S211, it is judged whether or not inputting of the name of the brazing alloy and the component name of the diode connector 30 to the input device 55 is acted. In detail, it is confirmed whether or not the name of the brazing alloy and the component name of the diode connector 30 are stored in the memory device 66. When the name of the brazing alloy and the component name of the diode connector 30 are stored both, it is judged that inputting to the input device 55 is acted (Y in S211) and the process proceeds to a step S251. When both of the name of the brazing alloy and the component name of the diode connector 30 are not stored, it is judged that inputting to the input device 51 is not acted (N in S211) and the process of S211 is repeated until the inputting is acted.

In the step S121, by collating the name of the brazing alloy stored in the memory device 66 to the melting point data J1 previously stored in the memory device 66, the melting point of the brazing alloy is led. After that, the process proceeds to a step S261.

In the step S261, by collating the area of the correlation function data in the memory device 66, the data showing the correlation function to be used is led. Based on the data showing the correlation function, the correlation function to be used is selected from the plurality of correlation functions previously stored in the memory device 66. By applying the melting point of the brazing alloy led in the step S251 as the heat temperature of the diode chip 33 to the selected correlation function, the total volume is calculated. The process proceeds to a step S262.

In the step S262, by collating the component name of the diode connector 30 stored in the memory device 66 to the total-volume limit data R3 stored in the memory device 66, the allowable maximum value of the total volume corresponding to the component name is led. Thereafter, the process proceeds to a step S263.

In the step S263, it is judged whether or not the total volume calculated in the step S261 is not larger than the allowable maximum value of the total volume led in the step S262. When the calculated total volume is not larger than the allowable maximum value (Y in S263), the total volume is determined and the process proceeds to a step S170. When the calculated total volume is larger than the allowable maximum value (N in S263), the process proceeds to a step S265 for changing the correlation function.

In the step S165, the data showing the correlation function stored in the area for storing the correlation function is changed to data showing the correlation function corresponding to diode chip 33 having an uprank chip size. In other words, when the data showing the correlation function (D) is stored, the data is changed to the data showing the correlation function (E). When the data showing the correlation function (E) is stored, the data is changed to the data showing the correlation function (F). Thereafter, the process proceeds to the step S261 for calculating total volume again.

In the step S270, the total volume determined in the step S263 is shown as the minimum value of the total volume and the allowable maximum value of the total volume led in the step S262 is shown as the maximum value of the total volume in the display device 12. Then, the process is stopped.

The steps S251, S261, S262, S263 and S265 correspond to the total-volume determining unit 67. The total-volume determining unit 62 structures the determining device.

One example of an operation for processing determination according to the present invention in the design apparatus 3 for designing the diode connector mentioned above will be described.

In the design apparatus 3 for designing a diode connector, when data showing the name of the brazing alloy, such as a number “21” indicating the brazing alloy of Sn/Zn 9.0, included in the melting point data J1 in FIG. 5 and the component name of the diode connector “DC-SS” are inputted in the input device 55, the melting point of 199° C. of the brazing alloy is led from the melting point data J1, referring the inputted “21” as index. Then, by applying the led melting point of 199° C. as the heat temperature of the diode chip 33 to the correlation function (D), the total volume of 161 mm cubic is calculated. Next, the allowable maximum value of 90 mm cubic is led from the total-volume limit data R3 by the component name “DC-SS” of the diode connector as an index. The calculated total volume of 161 mm cubic and the allowable maximum value of 90 mm cubic are compared. The calculated value is larger, so that the correlation function (D) is changed to correlation function (E).

By using the correlation function (E), the total volume is calculated again. The total volume becomes 101 mm cubic. The calculated total volume of 101 mm cubic and the allowable value of the total volume of 90 mm cubic are compared. The calculated total volume is still larger, so that the correlation function (E) is changed to the correlation function (F).

By using the correlation function (F), the total volume is calculated again. The total volume becomes 86 mm cubic. The calculated total volume of 86 mm cubic and the allowable value of the total volume of 90 mm cubic are compared. The calculated total volume is smaller, so that the total volume is determined. And, the determined total volume of 86 mm cubic as the minimum value of the total volume and the allowable maximum value of 90 mm cubic as the maximum value of the total value are shown on the display device, and the process is stopped.

As mentioned above, according to the embodiment, when the name of the brazing alloy and the component name of the diode connector 30 are inputted, the necessary total volume (i.e. the minimum value of the total volume) is determined based on the inputted name of the brazing alloy, the melting point data and the correlation functions (D)-(F), and the allowable maximum value of the total volume is determined based on the inputted component name of the diode connector 30 and the total-volume limit data R3. Thereby, the minimum value and the maximum value of the total volume of the lead frames 31, 32 and the bridge 34 of the diode connector 30 can be provided previously. By determining the total volume within the range defined by the minimum value and the maximum value, the diode connector 30 can be designed to fulfill the total volume limitation without melting the solder 35. Especially, by using the correlation functions (D)-(F) based on the allowable overcurrent, the diode connector 30 can be designed usable under the allowable overcurrent.

The correlation functions (D)-(F) can be formed with a linear function. By applying the heat temperature of the diode chip 33 (i.e. the melting point of the brazing alloy), the total volume of the lead frames 31, 32 and the bridge 34 can be calculated. Thereby, the total volume against the heat temperature can be calculated easily. Thus, the necessary minimum total volume can be easily calculated so that the diode connector can be easily and suitably designed.

By storing different correlation function for each chip size of the diode chip, the diode connector using the diode chip having different chip size can be designed, so that the various diode connectors can be provided. When the diode connector designed by using the diode chip 33 having certain chip size does not fulfill the correlation function corresponding to the diode chip 33, the diode chip 33 can be changed to other diode chip having different chip size. Thereby, the diode connector can be designed to correspond to wider condition by changing the diode chip 33. Thus, the diode connector having tight requirement about the outer dimensions can be designed easily.

By using the correlation functions (D)-(F) led by actual measured data, the diode connector 30 designed by the design apparatus 3 has heat dissipation performance in actual operation not far from the target design performance. When the actual operation of the diode connector 30 requires, in result, change of the total volume or the brazing alloy, large change is not required, so that the result of the actual operation can be fed back shortly to design process. Thus, design cycle time can be shortened and the design cost can be reduced.

In the third embodiment mentioned above, by storing the three correlation functions in the memory device 66, the correlation function is changed step by step when the total volume calculated based on the correlation function is larger than the allowable maximum value. The present invention is not limited as the embodiment, and by storing one correlation function, when the total volume calculated based on the one correlation function is larger than the allowable maximum value, error signal may be outputted and the process may be stopped. In the initial condition, other data than the correlation function (D) can be stored in the area for correlation function.

According to the third embodiment mentioned above, the name of the brazing alloy to be used is inputted and the melting point of the brazing alloy is led from the melting point data J1. The present invention is not limited as mentioned above, the melting point corresponding to the brazing alloy to be used may be directly inputted and the processes according to the present invention can be acted by using the inputted melting point without the melting point data J1.

According to the first, second and third embodiments as mentioned above, the necessary minimum value of the total volume can be led by calculating the total volume by applying the melting point of the brazing alloy as the heat temperature of the diode chip 33. By subtract 10° C. from the melting point of the brazing alloy as a margin, and applying the value as the heat temperature of the diode chip 33 lower 10° C. than the melting point of the brazing alloy, the total volume may be calculated. Thereby, the total volume increases, but the diode connector can have the margin of heating for actual operation.

According to the first and second embodiments mentioned above, the brazing alloy having the melting point not smaller than and closest to the calculated heat temperature of the diode chip is selected at the brazing-alloy determining units 23, 63. Therefore, when there is a plurality of the brazing alloys having the same melting point, the plurality of brazing alloys is selected. The brazing alloys having the same melting point may be previously stored in prioritized order, such as about cost, in the memory device 21, 61, and the brazing alloy is selected in the prioritized order. The brazing alloy having the melting point not smaller than the calculated heat temperature of the diode chip 33 can be used, so that the brazing alloy having the lowest cost may be selected from the brazing alloys having the melting point not smaller than the heat temperature of the diode chip 33 even if the melting point is not the closest to the heat temperature of the diode chip 33.

According to the first, second and third embodiments mentioned above, the design apparatus designs the diode connector having the pair of lead frames. The present invention is not limited, and can be applied to design the diode connector having three or more lead frames. According to the above embodiments, the bridge is arranged to straddle the pair of lead frames. The present invention is not limited, and can be applied to design the diode connector arranging a bridge to straddle among three or more lead frames for connecting them. For applying the present invention to design such diode connector, measuring actual data about the diode connector having such structure, leading the correlation function, and storing it in the memory device of the design apparatus are required.

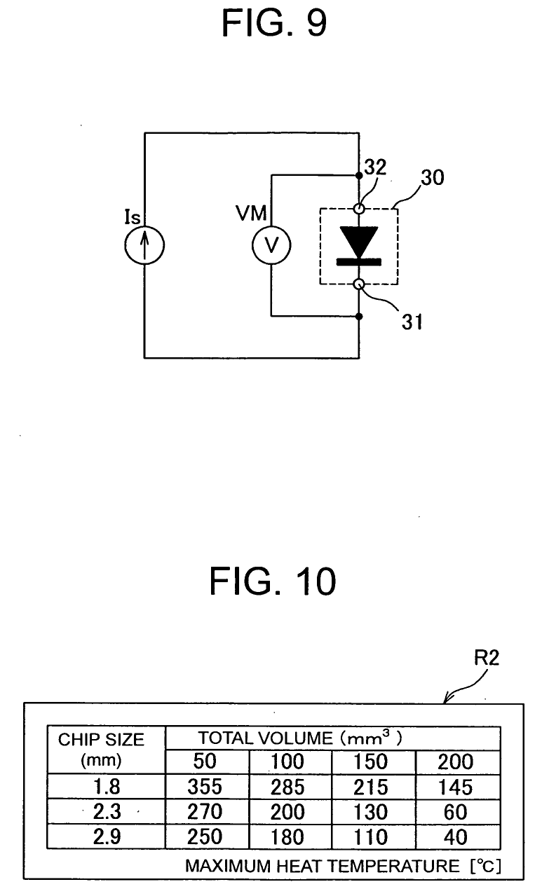

Next, the correlation function used in each of the embodiments mentioned above is shown with reference to FIGS. 9-11.

A plurality of diode connectors 30 having the diode chip 33, each diode chip with different chip size, is proto-typed, and a maximum heat temperature of the diode chip 33 when the predetermined allowable overcurrent is flown through the diode connector 30 is measured. By using the measuring results, relation of the total volume of the cathode-side lead frame 31, the anode-side lead frame 32 and the bridge 34, and the heat temperature of the diode chip 33 are plotted in a correlation graph (FIG. 6), and each of the correlation functions used in each of the above embodiments is led based on the correlation graph.

FIG. 9 shows a block diagram for measuring mentioned above. “Is” is a constant-current power supply for giving a constant current flow through the diode connector 30, and a usual direct-voltage/current generator is used for it. A positive electrode of the direct-current/voltage generator is connected to the anode-side lead frame 32, and a negative electrode thereof is connected to the cathode-side lead frame 31 by using covered wire with 80 A rated current to form an electric circuit. A voltage meter VM is arranged in parallel to the diode connector 30 between the anode-side lead frame 32 and the cathode-side lead frame 31, for measuring a voltage drop at the diode connector 30.

Measurement of the heat temperature of the diode chip 33 is acted as following. The diode connectors 30 each having total volume of 50 mm cubic, 100 mm cubic, 150 mm cubic and 200 mm cubic are respectively produced corresponding to each chip sizes of the diode chip 33 of 1.8 mm square, 2.3 mm square and 2.9 mm square. Each diode chip 33 has a correlation of the heat temperature and the voltage drop between the anode and cathode of the diode chip 33. The correlation data may be previously provided. Values of the allowable overcurrent for-the diode connector 30 mounted in a circuit having a fuse of a rated-current 10A are set, for example, at 20A/6 sec, 30A/3 sec, 40A/1 sec, 60A/0.5 sec, according to prearching time-current characteristic. By giving each allowable overcurrent flow in the diode connector 30 structured above, the heat temperature of the diode chip 33 is measured based on the voltage drop determined by the voltage meter VM and the correlation mentioned above.

Measurement was done for each of the diode connectors 30 mentioned above by using the above measuring structure. By giving the allowable overcurrent through the diode chip 33, each peak value (maximum value) of the heat temperatures of the diode chip 33 at respective allowable overcurrent was measured. For each chip size of the diode chips, the largest value is led from the peak value of the heat temperature as the largest heat temperature. The led data R2 is shown in FIG. 10. FIG. 6 is a correlation graph showing the led data R2 for each diode size of the diode chip 33.

The correlation graph shown in FIG. 6 is discussed herein. Each line shows the maximum heat temperature reducing in a constant ratio, i.e. changing linearly for increasing total volume. In other words, the line is a leaner function. Additionally, according to the chip size becoming larger, the line moves downwardly in the graph. Thus, larger chip size, smaller total volume can dissipate. The lines are in parallel to each other, so that rate of change of the maximum heat temperature of the diode chip against change of the total volume is constant without relation of the chip size of the diode chip.

By calculating the linear functions corresponding to lines based on the correlation graph, the above correlation functions (D)-(F) can be led. A temperature rate (i.e. gradient of the line) showing the change of the heat temperature of the diode chip 33 according to change of the total volume corresponding to each chip size of the diode chip 33 becomes −1.4. A temperature constant showing the heat temperature only of the diode chip 33 (i.e. total volume is zero) is 425 for the diode chip of 1.8 mm square, 340 for-the diode chip of 2.3 mm square, or 320 for the diode chip of 2.9 mm square.

Regarding relation between the total volume and the hate temperature of the diode chip, the correlation functions are led by actual measurement. The present invention is not limited so, and for example, a correlation of a total surface area of the lead frames and the bridge and the heat temperature of the diode chip can be applicable to design of the diode connector. However, the diode connector has limitations of the outer dimensions and its cost, so that the lead frames and the bridge cannot be changed large. Additionally, correlation functions between various alloys having different heat dissipations for the lead frames and the bridge can be led. Furthermore, the correlation functions can be led by the thermal analysis (simulation) in a computer without actual measurements.

According to the above measurement, the correlation is led by measuring the peak value (the maximum value) of the heat temperature of the diode chip when giving the overcurrent. The present invention is not limited so, and by measuring the maximum heat temperature when the maximum current in a normal operation flows constantly, a correlation of the maximum heat temperature and the total volume can be led. The correlation function can be determined suitably according to a condition of using the diode connector 30.

By using the design method for designing a diode connector according to the present invention, the maximum value and the minimum value of the total volume, which can be determined in a limitation of the outer dimensions of the package, can be led.

Firstly, by applying the melting point of the brazing alloy to be used in the diode connector to the correlation function corresponding to the chip size of the diode connector, the total volume is calculated. Next, allowable maximum value of the total volume is calculated by subtracting necessary minimum wall thickness for insulation from the outer dimensions of the packaging. When there is a plurality of usable brazing alloys, by selecting the brazing alloy having the lowest melting point from among them and applying it to the correlation function corresponding to the diode chip to be used, the minimum value of the total volume may be calculated. In other words, the diode connector having the total volume to allow the allowable overcurrent with the lowest melting point can allow the allowable overcurrent when using higher melting point.

Thus, the diode connector can be designed so as to make the lead frames and the bridge within the range acceptable for the total volume of the lead frames and the bridge. The diode connector fulfills the limitation of the outer dimensions usable under the allowable overcurrent. Therefore, the diode connector can be easily designed high reliable, in which the solder is not melted when the allowable overcurrent flows.

Next, it be shown that an available range of the total volume of the lead frames and the bridge of the diode connector is determined by the design apparatus 3 according to the third embodiment mentioned above. In each diode connector designed by the design apparatus 3, the component name of the diode connector, the chip size and number of the diode chip, and the brazing alloy (i.e. the melting point of the solder) are previously determined, so that each diode connector is designed according to each correlation function for each structure.

As shown in FIG. 14, the diode connector 30 has a rated current of 1.5 A, and includes two lead frames 31, 32, a diode chip (not shown) having a chip size of 2.3 mm square mounted on the lead frame 31, the bridge 34 connecting the two lead frames 31, 32 through the diode chip, and the package 37 arranging a part of the two lead frames 31, 32 and the bridge 34 inside thereof. Each of the lead frames 31, 32 and the bridge 34 are connected respectively by the solder having the melting point not lower than 190.2° C. The component name of the diode connector is “DC-S”. As shown in the total-volume limit data R3 in FIG. 12, the maximum outer dimensions of the package 37 has a limitation of depth 9.5 mm, width 7.8 mm, height 5.2 mm, and the allowable maximum value of the total volume is 243 mm cubic (calculated with the necessary wall thickness of 1.0 mm for insulation). According to the correlation graph shown in FIG. 6, the correlation function of the total volume “V” and the melting point of the solder Ts of the diode connector 30 is:

Ts≧(−1.4)*V+340 (G).

Therefore, the necessary minimum value of the total volume of the diode connector 30 shown in FIG. 14 becomes 107 mm cubic, and the maximum value becomes 243 mm cubic.

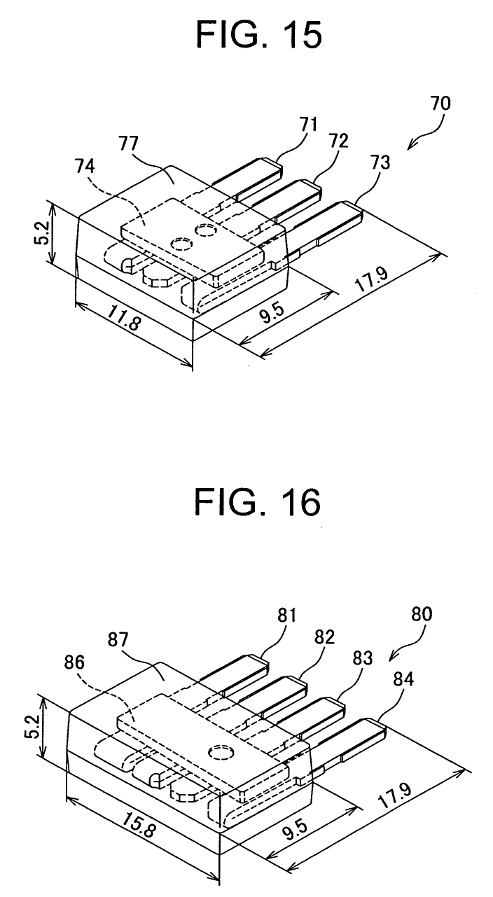

As shown in FIG. 15, the diode connector 70 has a rated current of 1.5 A, and includes three lead frames 71, 72, 73, two diode chips (not shown) having a chip size of 2.3 mm square mounted on the lead frames 71, 73, a bridge 74 connecting the three lead frames 71, 72, 73 through the diode chips, and a package 77 arranging a part of the three lead frames 71, 72, 73 and the bridge 74 inside thereof. Each of the lead frames 71, 72, 73 and the bridge 74 are connected respectively by the solder having the melting point not lower than 182.2° C. The component name of the diode connector is “DC-M”. As shown in the total-volume limit data R3 in FIG. 12, the maximum outer dimensions of the package 77 has a limitation of depth 9.5 mm, width 11.8 mm, height 5.2 mm, and the allowable maximum value of the total volume is 386 mm cubic (calculated with the necessary wall thickness of 1.0 mm for insulation). According to the correlation graph shown in FIG. 18, the correlation function of the total volume “V” and the melting point of the solder Ts of the diode connector 70 is:

Ts≧(−1.2)*V+300 (H).

Therefore, the necessary minimum value of the total volume of the diode connector 70 shown in FIG. 15 becomes 98.2 mm cubic, and the maximum value becomes 386 mm cubic. The correlation graph shown in FIG. 18 is given by actual measurement of giving the allowable overcurrent flow to the diode connector having three lead frames and two diode chips, similarly as the correlation graph shown in FIG. 6.

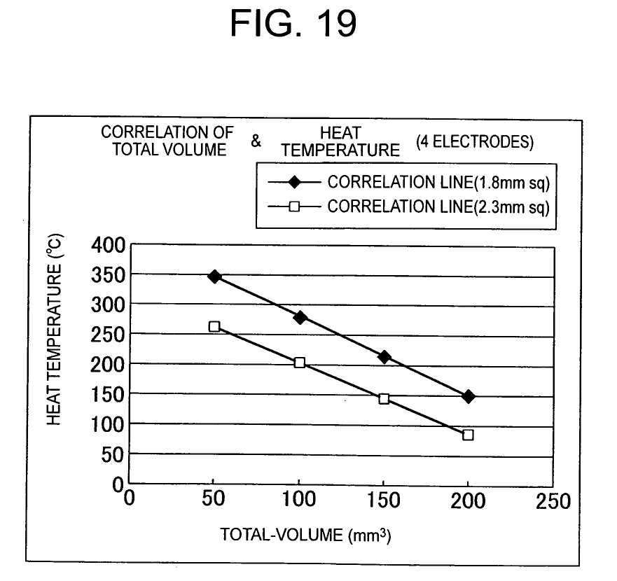

As shown in FIG. 16, the diode connector 80 has a rated current of 1.5 A, and includes four lead frames 81, 82, 83, 84, three diode chips (not shown) having a chip size of 2.3 mm square mounted on the lead frames 81, 82, 84, a bridge 86 connecting the four lead frames 81, 82, 83, 84 through the diode chips, and a package 87 arranging a part of the four lead frames 81, 82, 83, 84 and the bridge 86 inside thereof. Each of the lead frames 81, 82, 83, 84 and the bridge 86 are connected respectively by the solder having the melting point not lower than 163.0° C. The component name of the diode connector is “DC-L”. As shown in the total-volume limit data R3 in FIG. 12, the maximum outer dimensions of the package 87 has a limitation of depth 9.5 mm, width 15.8 mm, height 5.2 mm, and the allowable maximum value of the total volume is 528 mm cubic (calculated with the necessary wall thickness of 1.0 mm for insulation). According to the correlation graph shown in FIG. 19, the correlation function of the total volume “V” and the melting point of the solder Ts of the diode connector 80 is:

Ts≧(−1.2)*V+325 (I).

Therefore, the necessary minimum value of the total volume of the diode connector 80 shown in FIG. 16 becomes 135 mm cubic, and the maximum value becomes 528 mm cubic. The correlation graph shown in FIG. 19 is given by actual measurement of giving the allowable overcurrent flow to the diode connector 80 having four lead frames and three diode chips, similarly as the correlation graph shown in FIG. 6.

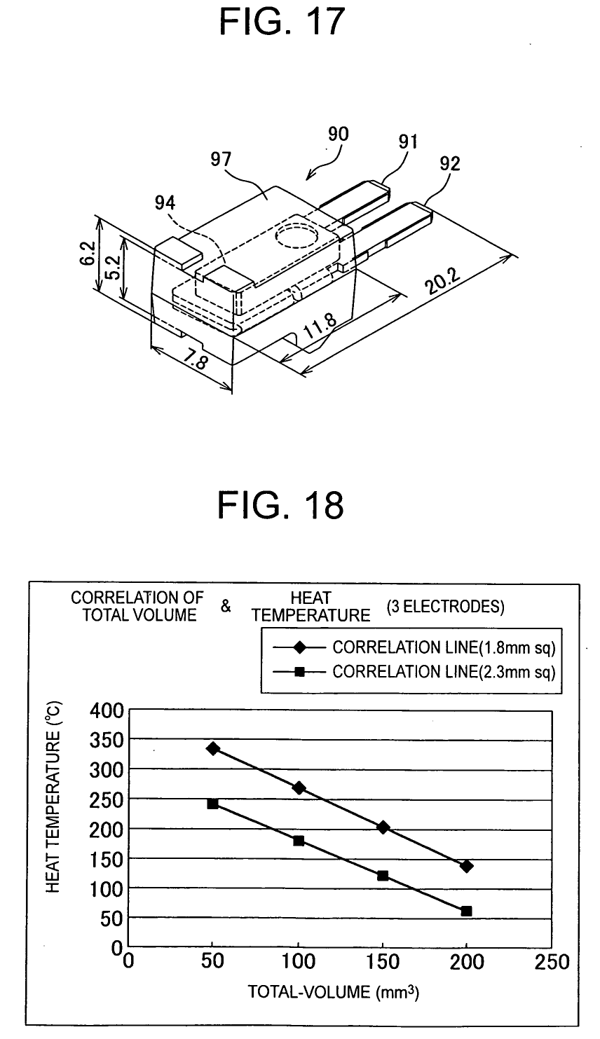

As shown in FIG. 17, the diode connector 90 has a rated current of 3 A, and includes two lead frames 91, 92, one diode chip (not shown) having a chip size of 2.9 mm square mounted on the lead frames 91, 92, a bridge 94 connecting the two lead frames 91, 92 through the diode chip, and a package 97 arranging a part of the two lead frames 91, 92 and the bridge 94 inside thereof. Each of the lead frames 91, 92 and the bridge 94 are connected respectively by the solder having the melting point not lower than 126.8° C. The component name of the diode connector is “DC-T”. As shown in the total-volume limit data R3 in FIG. 12, the maximum outer dimensions of the package 97 has a limitation of depth 11.8 mm, width 7.8 mm, height 5.2 mm (6.2 mm including a projection), and the allowable maximum value of the total volume is 308 mm cubic. According to the correlation graph shown in FIG. 6, the correlation function of the total volume “V” and the melting point of the solder Ts of the diode connector 80 is:

Ts≧(−1.4)*V+320 (J).

Therefore, the necessary minimum value of the total volume of the diode connector 90 shown in FIG. 17 becomes 138 mm cubic, and the maximum value becomes 308 mm cubic.

In the diode connector 30, 70, 80, 90, the minimum value and the maximum value of the total volume of the lead frames and the bridge to be allowed are determined. Thus, the diode connector can be designed so as to make the lead frames and the bridge within the range acceptable for the total volume of the lead frames and the bridge. Thereby, the diode connector fulfills the limitation of the outer dimensions without melting the solder under the current flow.

It is further understood by those skilled in the art that the foregoing description is preferred embodiments according to the present invention and that various changes and modifications may be made in the present invention without departing from the spirit and scope thereof.

1. A design apparatus for designing a diode connector, the diode connector, comprising:
a plurality of lead frames having a joint and a terminal formed integrally with the joint;
at least one diode chip arranged on the joint of at least one of the plurality of lead frames;
a bridge connecting between the diode chip and the joint of at least other one of the plurality of lead frames; and
a solder welding the joint of the lead frame, the diode chip and the bridge to each other,
the design apparatus, comprising:
a memory device storing melting point data of a plurality of brazing alloys, and correlation data between a total volume of the lead frames and the bridge, and heating temperature of the diode chip;
an input device for inputting one of a name of the brazing alloy to be used selected from the plurality of brazing alloys and the total volume; and
a determination device for determining the other one of the name of the brazing alloy and the total volume based on the one of the name of the brazing alloy and the total volume, which is inputted into the input device, and the melting point data and correlation data, which are stored in the memory device.

2. A design apparatus for designing a diode connector, the diode connector, comprising:
a plurality of lead frames having a joint and a terminal formed integrally with the joint;
at least one diode chip arranged on the joint of at least one of the plurality of lead frames;
a bridge connecting between the diode chip and the joint of at least other one of the plurality of lead frames; and
a solder welding the joint of the lead frame, the diode chip and the bridge to each other,
the design apparatus, comprising:
a memory device storing melting point data of a plurality of brazing alloys, correlation data between a total volume of the lead frames and the bridge, and heating temperature of the diode chip, a component name of the diode connector and total-volume limitation data about a maximum allowable value of the total volume corresponding to the diode connecter specified by the component name;
an input device for inputting a name of the brazing alloy to be used selected from the plurality of brazing alloys and the component name of the diode connector; and
a determination device for determining a maximum value and a minimum value of the total volume based on the name of the brazing alloy, the component name of the diode connector, which are inputted into the input device, the melting point data, the correlation data and total-volume limitation data which are stored in the memory device.

3. The design apparatus for designing a diode connector according to claim 1, wherein the memory device stores a plurality of the correlation data different from each other and defined corresponding to each diode chip.

4. The design apparatus for designing a diode connector according to claim 1, wherein the correlation data is defined by a formula:
Td=h*V+a;
herein Td is the heating temperature of the diode chip, and “h” is a temperature coefficient indicating changing ratio of the heating temperature of the diode chip against change of the total volume, and “V” is the total volume, and “a” is a temperature constant to be different from each diode chip.

5. A design method of designing a diode connector, the diode connector, comprising:
a plurality of lead frames having a joint and a terminal formed integrally with the joint;
at least one diode chip arranged on the joint of at least one of the plurality of lead frames;
a bridge connecting between the diode chip and the joint of at least other one of the plurality of lead frames; and
a solder welding the joint of the lead frame, the diode chip and the bridge to each other,
the design method, comprising the steps of:
storing melting point data of a plurality of brazing alloys, and correlation data between a total volume of the lead frames and the bridge, and heating temperature of the diode chip;
selecting one of a name of the brazing alloy to be used selected from the plurality of brazing alloys and the total volume; and
determining the other one of the name of the brazing alloy and the total volume based on the one of the name of the brazing alloy and the total volume, which is selected, and the melting point data and correlation data, which are stored.

6. A design method of designing a diode connector, the diode connector, comprising:
a plurality of lead frames having a joint and a terminal formed integrally with the joint;
at least one diode chip arranged on the joint of at least one of the plurality of lead frames;
a bridge connecting between the diode chip and the joint of at least other one of the plurality of lead frames; and
a solder welding the joint of the lead frame, the diode chip and the bridge to each other,
the design method, comprising the steps of:
storing melting point data of a plurality of brazing alloys, correlation data between a total volume of the lead frames and the bridge, and heating temperature of the diode chip, a component name of the diode connector and total-volume limitation data about a maximum allowable value of the total volume corresponding to the diode connecter specified by the component name;
inputting a name of the brazing alloy to be used selected from the plurality of brazing alloys and the component name of the diode connector; and
determining a maximum value and a minimum value of the total volume based on the name of the brazing alloy, the component name of the diode connector, which are inputted into the input device, the melting point data, the correlation data and total-volume limitation data which are stored in the memory device.

7. A diode connector, comprising:
a plurality of lead frames having a joint and a terminal formed integrally with the joint;
at least one diode chip arranged on the joint of at least one of the plurality of lead frames;
a bridge connecting between the diode chip and the joint of at least other one of the plurality of lead frames; and
a solder welding the joint of the lead frame, the diode chip and the bridge to each other,
wherein a relation defined by a formula:
Ts≧h*V+a;
herein Ts is a melting point of the solder, and “V” is a total volume of the lead frames and the bridge, and “h” is a temperature coefficient indicating changing ratio of the heating temperature of the diode chip against change of the total volume, and “a” is a temperature constant to be different from each diode chip: is fulfilled.

8. The diode connector according to claim 7, further comprising a package arranging the joint and the bridge of the plurality of lead frames inside the package and exposing the terminals of the plurality of lead frames from the package,
wherein the one diode is arranged in the package and a chip size of the one diode is 2.3 mm square,
wherein the total volume of the lead frames and the bridge is not less than 107 mm cubic and not more than 243 mm cubic, when upper limits of outer dimensions of the package are 9.5 mm depth, 7.8 mm width, 5.2 mm height.

9. The diode connector according to claim 7, further comprising a package arranging the joint and the bridge of the plurality of lead frames inside the package and exposing the terminals of the plurality of lead frames from the package,
wherein two diodes are arranged in the package and a chip size of the two diodes is 2.3 mm square,
wherein the total volume of the lead frames and the bridge is not less than 98.2 mm cubic and not more than 386 mm cubic, when upper limits of outer dimensions of the package are 9.5 mm depth, 11.8 mm width, 5.2 mm height.

10. The diode connector according to claim 7, further comprising a package arranging the joint and the bridge of the plurality of lead frames inside the package and exposing the terminals of the plurality of lead frames from the package,
wherein three diodes are arranged in the package and a chip size of the three diodes is 2.3 mm square,
wherein the total volume of the lead frames and the bridge is not less than 135 mm cubic and not more than 528 mm cubic, when upper limits of outer dimensions of the package are 9.5 mm depth, 15.8 mm width, 5.2 mm height.

11. The diode connector according to claim 7, further comprising a package arranging the joint and the bridge of the plurality of lead frames inside the package and exposing the terminals of the plurality of lead frames from the package,
wherein one diode is arranged in the package and a chip size of the one diode is 2.9 mm square,
wherein the total volume of the lead frames and the bridge is not less than 138 mm cubic and not more than 308 mm cubic,
when upper limits of outer dimensions of the package are 11.8 mm depth, 7.8 mm width, 5.2 mm height.

12. The design apparatus for designing a diode connector according to claim 2, wherein the memory device stores a plurality of the correlation data different from each other and defined corresponding to each diode chip.

13. The design apparatus for designing a diode connector according to claim 2, wherein the correlation data is defined by a formula:
Td=h*V+a;
herein Td is the heating temperature of the diode chip, and “h” is a temperature coefficient indicating changing ratio of the heating temperature of the diode chip against change of the total volume, and “V” is the total volume, and “a” is a temperature constant to be different from each diode chip.

14. The design apparatus for designing a diode connector according to claim 3, wherein the correlation data is defined by a formula:
Td=h*V+a;
herein Td is the heating temperature of the diode chip, and “h” is a temperature coefficient indicating changing ratio of the heating temperature of the diode chip against change of the total volume, and “V” is the total volume, and “a” is a temperature constant to be different from each diode chip.
